(19) United States
(12) Patent Application Publication
(10) Pub. No.: US 2025/0142913 A1
(43) Pub. Date: May 1, 2025

(54) PERIPHERAL CIRCUIT WITH SEMICONDUCTOR PILLAR CONTAINING LOCAL INTERCONNECTS AND METHODS FOR FORMING THE SAME

(71) Applicant: WESTERN DIGITAL TECHNOLOGIES, INC., SAN JOSE, CA (US)

(72) Inventors: Hokuto KODATE, Nagoya (JP); Eiichi FUJIKURA, Yokkaichi (JP)

(21) Appl. No.: 18/495,552

(22) Filed: Oct. 26, 2023

(51) Int. Cl. H01L 29/45; H01L 21/768; H01L 23/522; H01L 27/092; H01L 29/40; H10B 41/27; H10B 41/40; H10B 43/27; H10B 43/40

(52) U.S. Cl. CPC H10D 62/83; H01L 21/76843; H01L 23/5226; H10B 41/27; H10B 41/40; H10B 43/27; H10B 43/40; H10D 64/01; H10D 64/62; H10D 84/85

(57) ABSTRACT

A device structure includes a first field effect transistor, a second field effect transistor, and a local interconnect structure. The local interconnect structure includes a first semiconductor pillar structure contacting a top surface of an active region of the first field effect transistor, a metallic structure contacting a top surface of the first semiconductor pillar structure, and a second semiconductor pillar structure contacting an electrical node of the second field effect transistor.

### FIELD

The present disclosure relates generally to the field of semiconductor devices, and particularly to a peripheral circuit with semiconductor pillar containing local interconnects for a three-dimensional memory device and methods for forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises a first field effect transistor; a second field effect transistor; and a local interconnect structure that includes: a first semiconductor pillar structure contacting a top surface of an active region of the first field effect transistor; a first metallic contact via structure contacting a top surface of the first semiconductor pillar structure; a metallic structure contacting a top surface of the first metallic contact via structure; and a second metallic contact via structure contacting a bottom surface of the metallic structure and electrically connected to an electrical node of the second field effect transistor.

According to another aspect of the present disclosure, a method of forming a device structure comprises forming field effect transistors on a substrate, wherein the field effect transistors comprise gate stack structures including a respective gate dielectric, a respective gate electrode, and a respective gate cap dielectric; forming a gate-level dielectric layer, wherein a topmost surface of the gate-level dielectric layer is formed within a horizontal plane including top surfaces of the gate cap dielectrics of the field effect transistors; forming pedestal-contact via cavities through at least the gate-dielectric layer over a first subset of active regions of the field effect transistors; forming semiconductor pillar structures in lower portions of the pedestal-contact via cavities, wherein the semiconductor pillar structures comprise a first semiconductor pillar structure contacting an active region of a first field effect transistor of the field effect transistors; forming metallic contact via structures after formation of the semiconductor pillar structures, wherein the metallic contact via structures comprise a first metallic contact via structure that is formed on a top surface of the first semiconductor pillar structure and a second metallic contact via structure that is electrically connected to a node of a second field effect transistor of the field effect transistors; and forming a metallic structure contacting a top surface of the first metallic contact via structure and the second metallic contact via structure.

### BRIEF DESCRIPTION OF THE DRAWINGS

FIG. 1A is a schematic vertical cross-sectional view of an exemplary structure for forming a memory die after formation of shallow trench isolation structures and gate stack structures according to embodiments of the present disclosure. FIG. 1B is a magnified view of a portion of a peripheral region 200 in the exemplary structure of FIG. 1A.

FIGS. 2A-2J are sequential vertical cross-sectional views of a portion of the peripheral region of the exemplary structure during formation of semiconductor pillar structures and metallic contact via structures according to the embodiments of the present disclosure.

FIGS. 3A-3C are sequential vertical cross-sectional views of a portion of the peripheral region of a first configuration of the exemplary structure during formation of metallic line structures and capping-level dielectric layers according to a first embodiment of the present disclosure.

FIG. 4 is a vertical cross-sectional views of a portion of the peripheral region of a second configuration of the exemplary structure after formation of a passivation capping layer according to a second embodiment of the present disclosure.

FIG. 5A is a vertical cross-sectional view of the exemplary structure after deposition and patterning of a first alternating stack of first insulating layers and first sacrificial material layers according to the first and second embodiments of the present disclosure. FIG. 5B is a magnified view of a portion of a peripheral region in the first configuration of the exemplary structure of the first embodiment after the processing steps of FIG. 5A. FIG. 5C is a magnified view of a portion of a peripheral region in the second configuration of the exemplary structure of the second embodiment after the processing steps of FIG. 5A.

FIG. 6A is a vertical cross-sectional view of the exemplary structure after formation of a first retro-stepped dielectric material portion according to the embodiments of the present disclosure. FIG. 6B is a magnified view of a portion of a peripheral region in the first configuration of the exemplary structure of the first embodiment after the processing steps of FIG. 6A. FIG. 6C is a magnified view of a portion of a peripheral region in the second configuration of the exemplary structure of the second embodiment after the processing steps of FIG. 6A.

FIG. 7A is a vertical cross-sectional view of the exemplary structure after formation of first-tier openings according to the embodiments of the present disclosure. FIG. 7B is a top-down view of the exemplary structure of FIG. 7A. The zig-zag plane A-A′ corresponds to the cut plane of the vertical cross-sectional view of FIG. 7A.

FIG. 8 is a vertical cross-sectional view of the exemplary structure after formation of sacrificial opening fill structures according to the embodiments of the present disclosure.

FIG. 9A is a vertical cross-sectional view of the exemplary structure after formation of first-tier metal interconnect structures according to the embodiments of the present disclosure. FIG. 9B is a top-down view of the exemplary structure of FIG. 9A. The zig-zag plane A-A′ corresponds to the cut plane of the vertical cross-sectional view of FIG. 9A. FIGS. 9C, 9D, and 9E are magnified views of a portion of a peripheral region in the first, second, and third configurations, respectively, of the exemplary structure of the first, second and third embodiments, respectively, after the processing steps of FIGS. 9A and 9B.

FIG. 10 is a vertical cross-sectional view of the exemplary structure after deposition and patterning of a second alternating stack of second insulating layers and second sacrificial material layers and after formation of a second retro-stepped dielectric material portion according to the embodiments of the present disclosure.

FIG. 11 is a vertical cross-sectional view of the exemplary structure after formation of second-tier openings according to the embodiments of the present disclosure.

FIG. 12 is a vertical cross-sectional view of the exemplary structure after formation of inter-tier openings according to the embodiments of the present disclosure.

FIG. 13A is a vertical cross-sectional view of the exemplary structure after formation of memory opening fill structures and support pillar structures according to the embodiments of the present disclosure. FIG. 13B is a top-down view of the exemplary structure of FIG. 13A. The zig-zag plane A-A′ corresponds to the cut plane of the vertical cross-sectional view of FIG. 13A.

FIG. 14A is a vertical cross-sectional view of the exemplary structure after formation of a contact-level dielectric layer and lateral isolation trenches according to the embodiments of the present disclosure. FIG. 14B is a top-down view of the exemplary structure of FIG. 14A. The zig-zag plane A-A′ corresponds to the cut plane of the vertical cross-sectional view of FIG. 14A.

FIG. 15 is a vertical cross-sectional view of the exemplary structure after formation of lateral recesses according to the embodiments of the present disclosure.

FIG. 16 is a vertical cross-sectional view of the exemplary structure after formation of electrically conductive layers according to the embodiments of the present disclosure.

FIG. 17A is a vertical cross-sectional view of the exemplary structure after formation of isolation trench fill structures according to the embodiments of the present disclosure. FIG. 17B is a top-down view of the exemplary structure of FIG. 17A. The zig-zag plane A-A′ corresponds to the cut plane of the vertical cross-sectional view of FIG. 17A.

FIG. 18A is a vertical cross-sectional view of the exemplary structure after formation of various contact via structures and second-tier metal interconnect structures according to the embodiments of the present disclosure. FIG. 18B is a top-down view of the exemplary structure of FIG. 18A. The zig-zag plane A-A′ corresponds to the cut plane of the vertical cross-sectional view of FIG. 18A. FIGS. 18C, 18D, and 18E are magnified views of a portion of a peripheral region in the first, second, and third configurations, respectively, of the exemplary structure of the first, second and third embodiments, respectively, after the processing steps of FIGS. 18A and 18B.

FIG. 19 is a vertical cross-sectional view of the exemplary structure after formation of upper dielectric material layers and upper metal interconnect structures according to the embodiments of the present disclosure.

### DETAILED DESCRIPTION

As discussed above, the embodiments of the present disclosure are directed to a device structure including semiconductor pillar containing local interconnects for a peripheral circuit of a three-dimensional memory device and methods for forming the same, of which various aspects are now described in detail. Embodiments of the disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

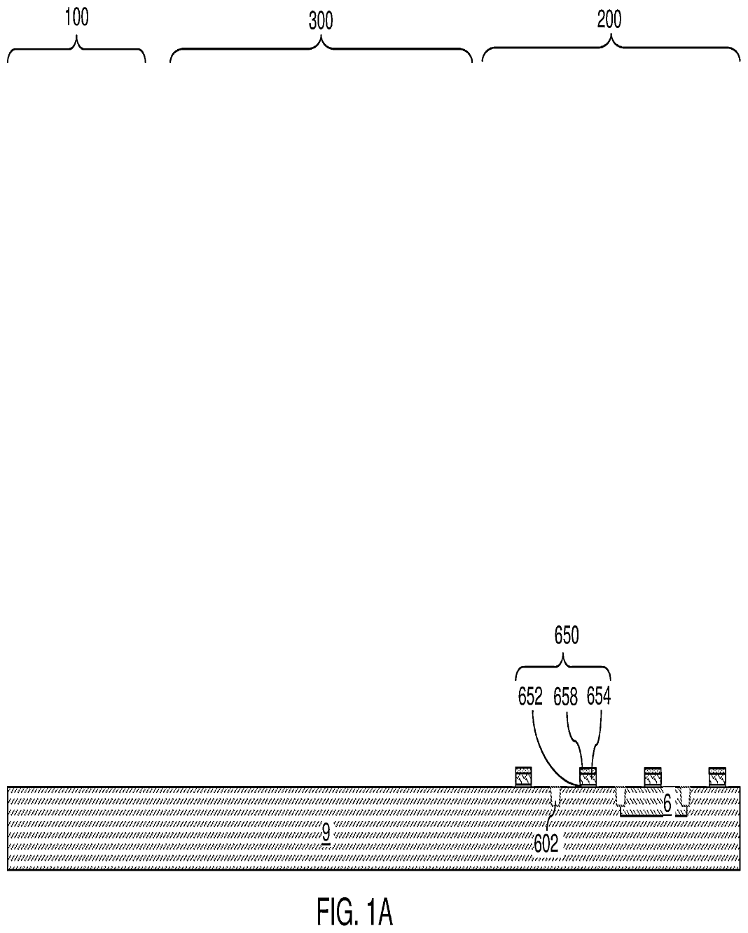

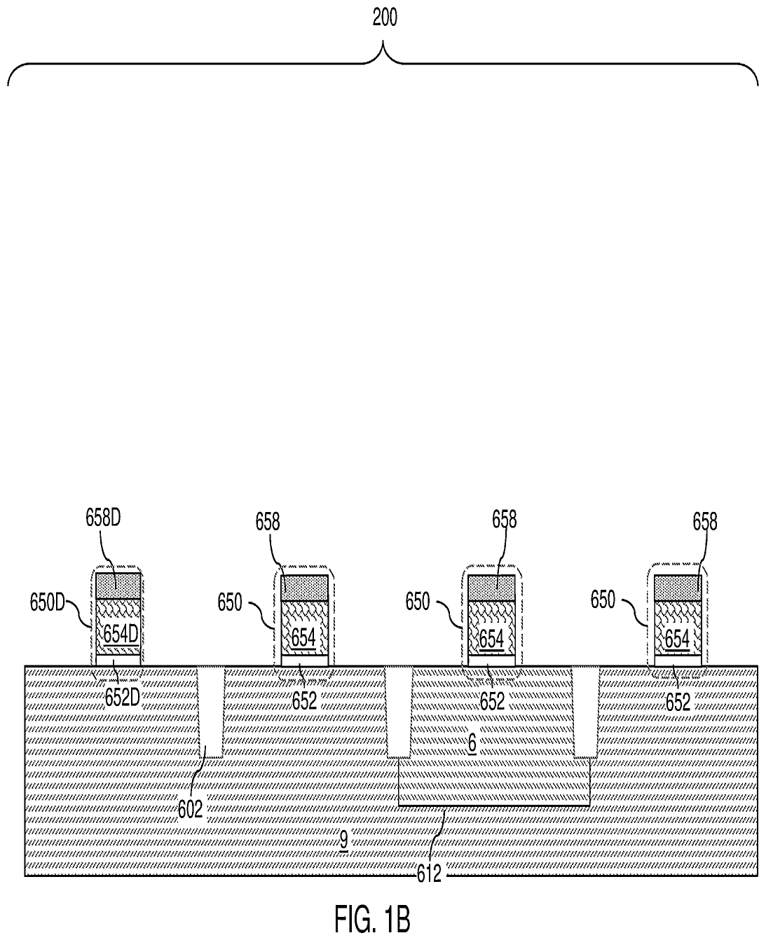

Referring to FIGS. 1A and 1B, an exemplary structure according to various embodiments of the present disclosure comprises a substrate 9, which may be a semiconductor substrate, such as a single-crystalline silicon substrate or a semiconductor-on-insulator substrate including a single-crystalline semiconductor layer at least at an upper portion thereof. In one embodiment, the substrate 9 may comprise a commercially available single-crystalline silicon wafer, on which a two-dimensional array of memory dies are formed. Each memory die may comprise at least one memory array region 100 in which a three-dimensional memory array is to be subsequently formed, at least one contact region 300 in which layer contact via structures contacting a respective electrically conductive layer are to be subsequently formed, and a peripheral region 200 in which a peripheral circuit (i.e., driver circuit) including semiconductor devices configurated to control operation of the three-dimensional memory array. The illustrated portion of the memory die in FIG. 1A corresponds to a portion of the memory die.

Masked ion implantation processes can be performed to form various doped wells 6 as needed. The illustrated configuration corresponds to a case in which an upper portion of the substrate 9 comprises a p-doped single-crystalline semiconductor material (e.g., portion of a p-type doped silicon wafer), and doped wells 6 include at least one n-doped single-crystalline semiconductor material (e.g., n-type doped silicon). Typically, the net atomic concentration of electrical dopants in the p-doped single-crystalline semiconductor material layer or in the doped wells 6 may be in a range from 1.0×10¹⁴/cm³ to 1.0×10¹⁷/cm³, although lesser and greater net atomic concentrations may also be employed. As used herein, a net atomic concentration refers to the absolute value of the difference between the atomic concentration of p-type electrical dopants and the atomic concentration of n-type electrical dopants.

Shallow trench isolation structures 602 may be formed in the peripheral region 200 to laterally enclose discrete surface semiconductor material portions (e.g., transistor areas) of the substrate 9. Gate stack structures 650 can be formed over the surface portions of the substrate 9 that are laterally surrounded by a respective one of the shallow trench isolation structures 602. Each of the gate stack structures 650 may comprise a respective vertical stack of a gate dielectric 652, a gate electrode 654, and a gate cap dielectric 658. Each gate dielectric 652 comprises a respective gate dielectric material, such as silicon oxide. Each gate electrode 654 may comprise an electrically conductive gate electrode material. In one embodiment, the gate electrodes 654 may comprise doped polysilicon. In one embodiment, the gate electrodes 654 may comprise n-doped polysilicon having an atomic concentration of electrical dopants in a range from 1.0×10¹⁸/cm³ to 1.0×10²¹/cm³, although lesser and greater net atomic concentrations may also be employed. The thickness of the gate electrodes 654 may be in a range from 100 nm to 300 nm, although lesser and greater thicknesses may also be employed. The gate cap dielectrics 658 comprise a dielectric material, such as silicon nitride, and may have a thickness in a range from 20 nm to 100 nm, such as from 30 nm to 60 nm, although lesser and greater thicknesses may also be employed.

In one embodiment shown in FIG. 1B, a dummy gate stack structure 650D may be formed at a periphery of the peripheral region 200 adjacent to the contact region 300. The dummy gate stack structure 650D may be subsequently employed as a diffusion blocker structure that is not electrically active. The dummy gate stack structure 650D may comprise a stack of a dummy gate dielectric 652D, a dummy gate electrode 654D, and a dummy gate cap dielectric 658D.

While FIGS. 1A and 1B illustrate areas for forming three field effect transistors and one dummy field effect transistor, it is understood that typically millions or billions of field effect transistors can be formed in the peripheral region 200 in each memory die. Thus, the illustrated examples of the field effect transistors are merely representative of typical examples of the field effect transistors, and the present disclosure allows formation of additional type of semiconductor devices in the peripheral region 200 or in additional regions that are not illustrated.

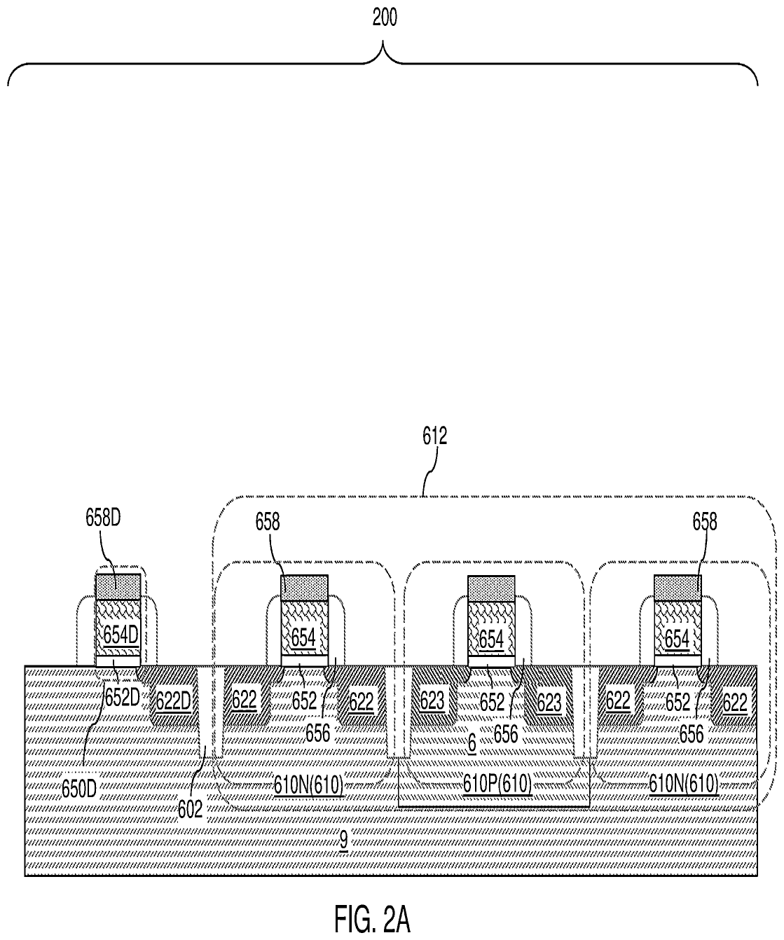

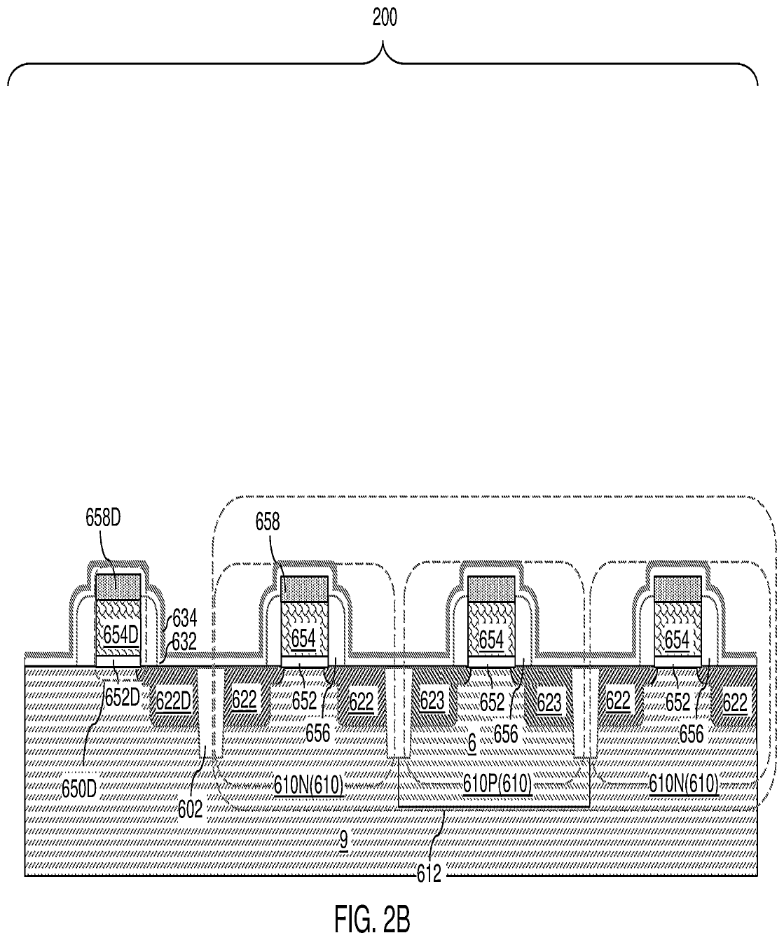

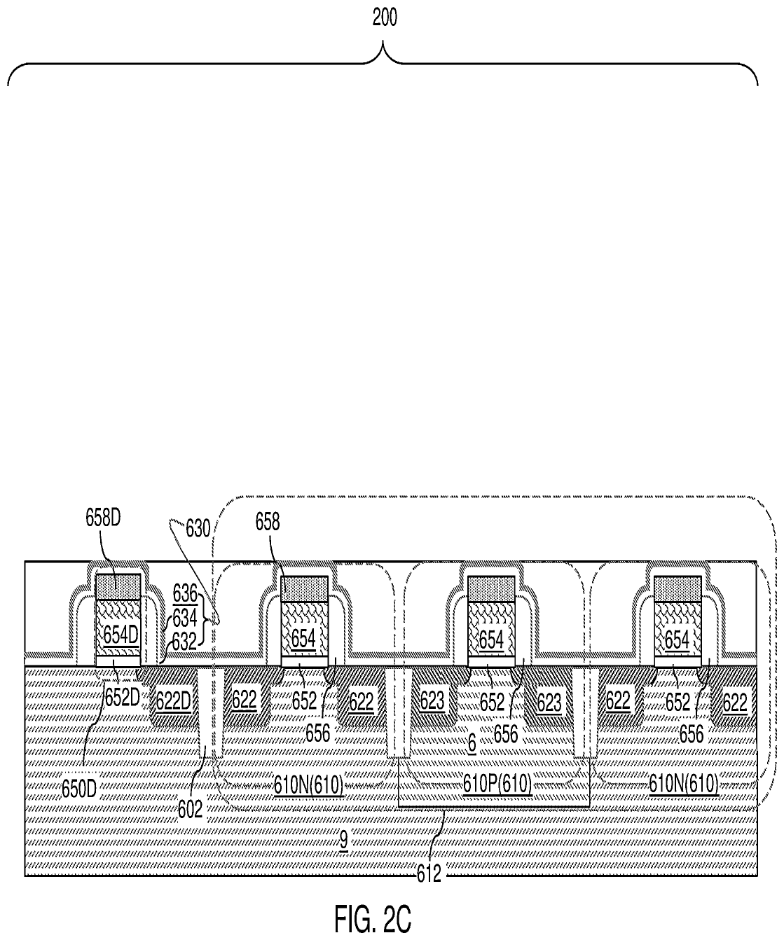

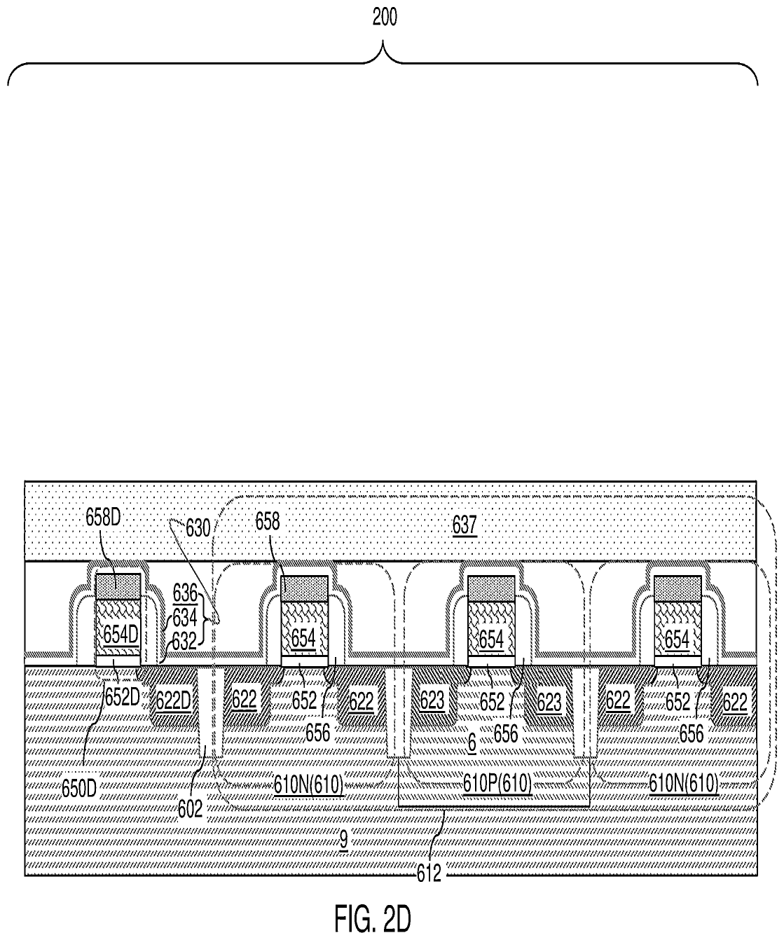

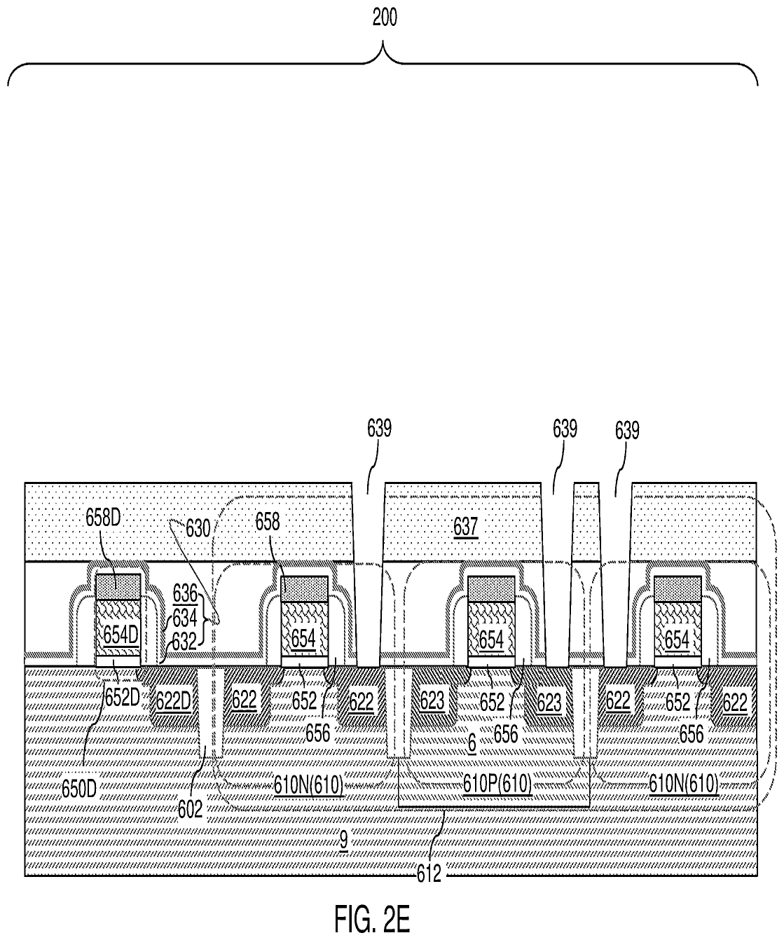

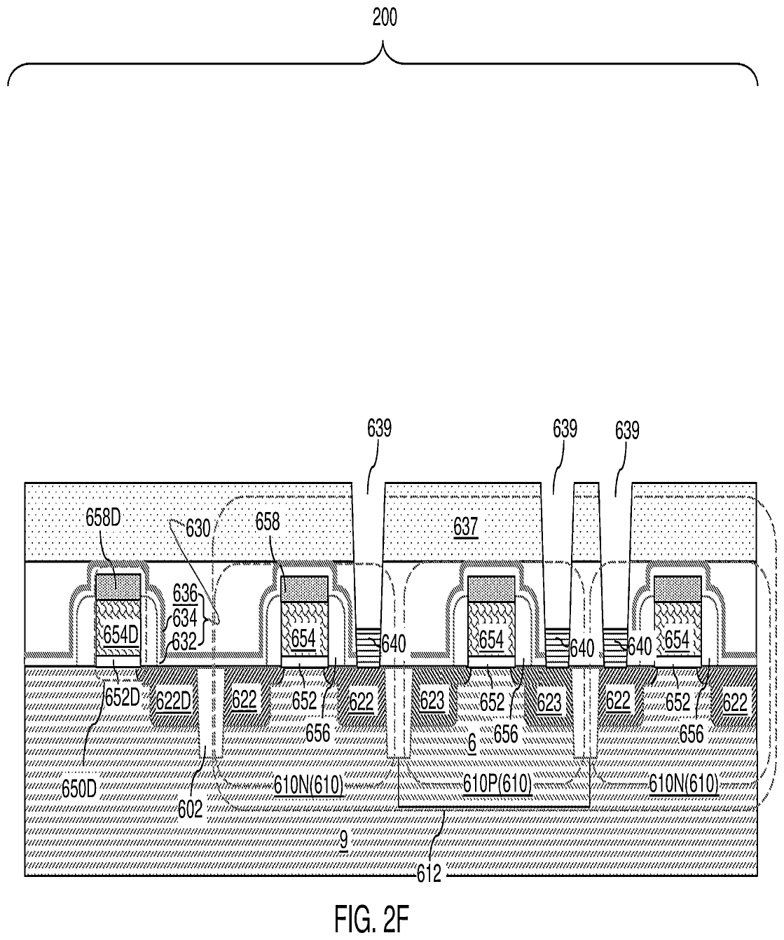

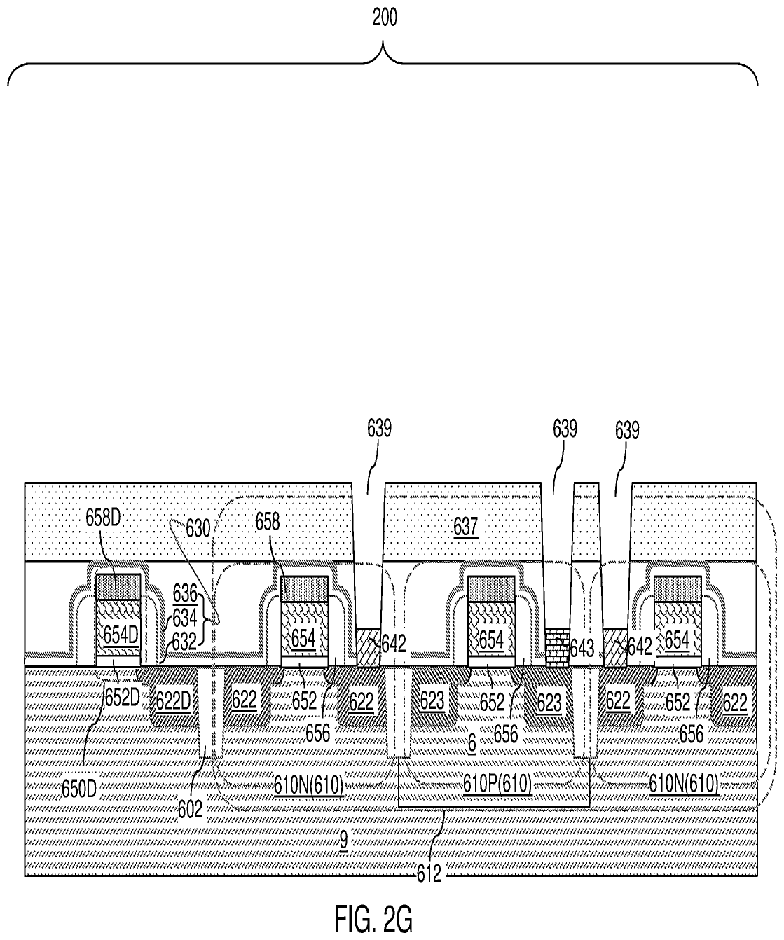

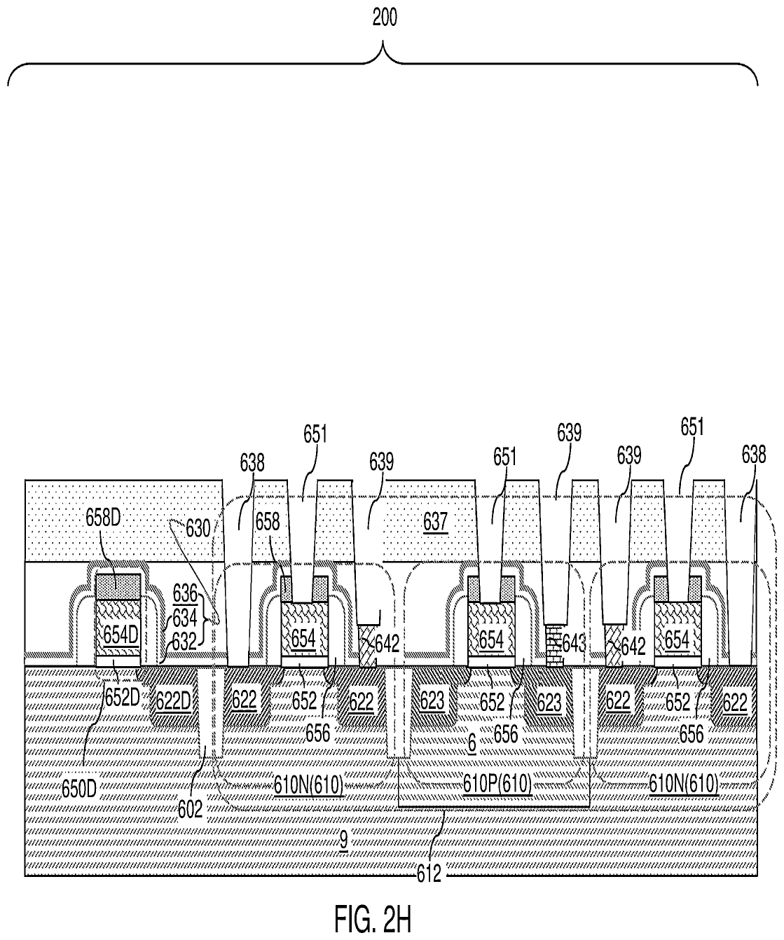

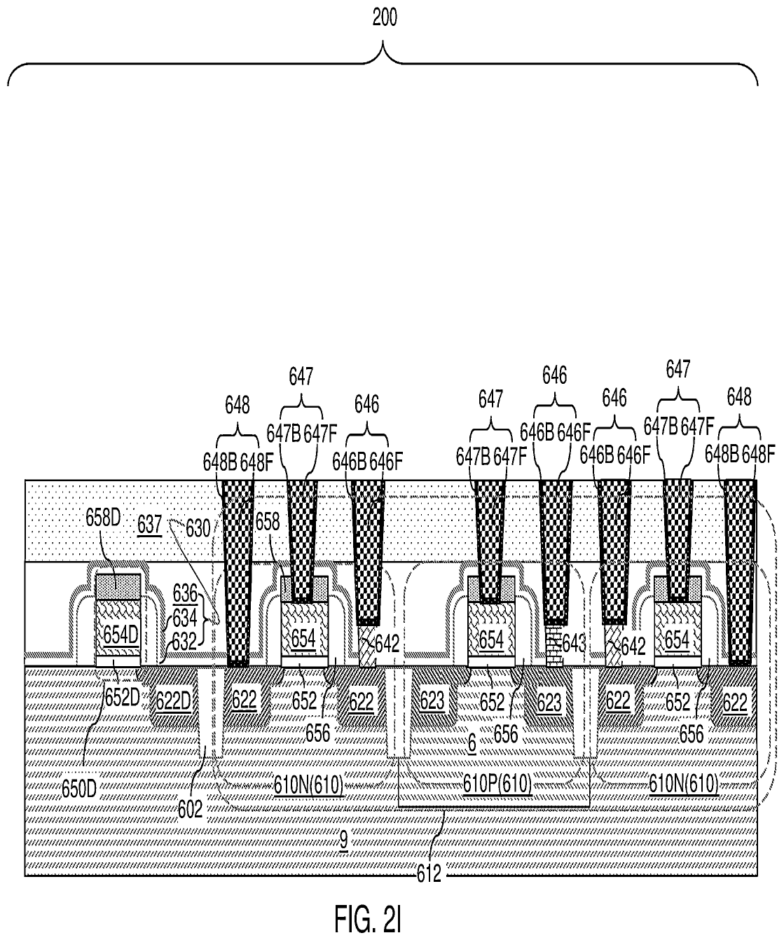

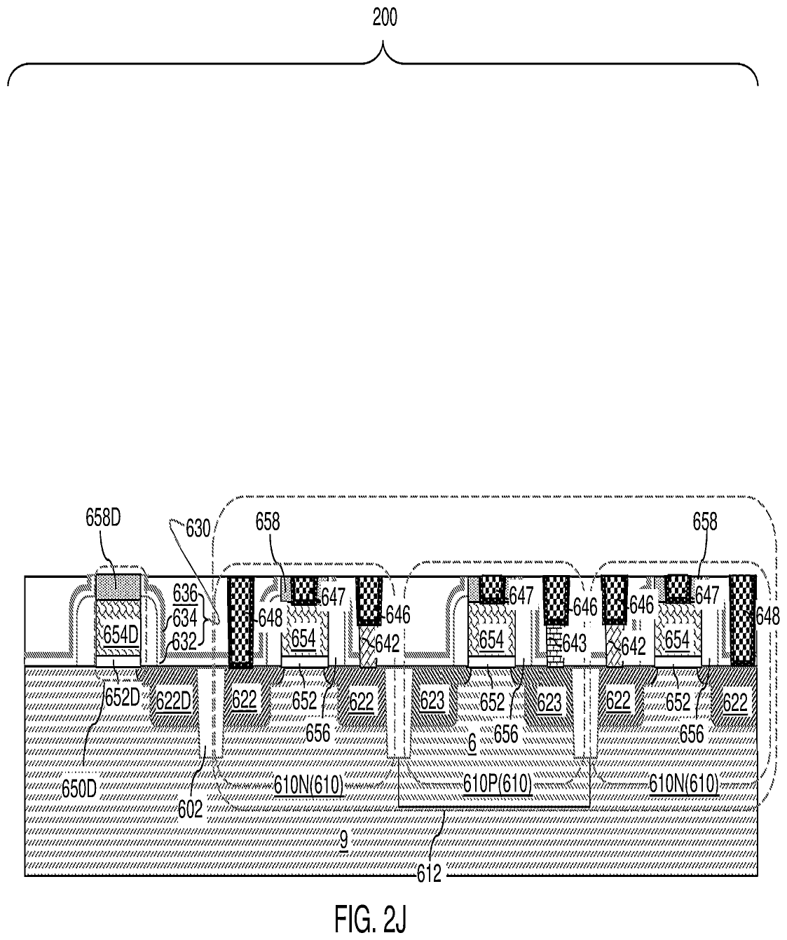

FIGS. 2A-2J are sequential vertical cross-sectional views of a portion of the peripheral region 200 of the exemplary structure during formation of semiconductor pillar structures (642, 643) and metallic contact via structures (647, 648, 646) according to an embodiment of the present disclosure.

Referring to FIG. 2A, various processing steps, such as photolithography, ion implantation, layer deposition and etching, are performed to form field effect transistors 610 in the peripheral region 200. Each of the field effect transistors 610 may comprise a respective pair of active regions (622 or 623). As used herein, an “active region” of a field effect transistor refers to a source region or a drain region in case a source extension region or a drain extension region is not employed, and refers to a combination of a source region and a source extension region or a combination of a drain region and a drain extension region if a source extension region or a drain extension region is present in the field effect transistor. If source drain extension regions (as incorporated into the active regions) are formed, gate spacers 656 may be formed around the gate stack structures 650.

Generally, the field effect transistors 610 may comprise p-type field effect transistors 610P and n-type field effect transistors 610N. Each n-type field effect transistor 610N may comprise a respective pair of n-doped active regions 622. Each p-type field effect transistor 610P may comprise a respective pair of p-doped active regions 623. A dummy active region 622D may be formed adjacent to the dummy gate stack structure 650D. A peripheral circuit (e.g., driver circuit) 612 may comprise a plurality of p-type field effect transistors 610P, a plurality of n-type field effect transistors 610N, and optionally additional semiconductor devices (not shown) such as resistors, capacitors, diodes, etc. At least some of the pairs of p-type field effect transistors 610P and the n-type field effect transistors 610N may be arranged in a CMOS configuration.

Referring to FIG. 2B, a first dielectric liner 632 and/or a second dielectric liner 634 may be optionally formed over the field effect transistors 610 by a respective conformal deposition process (such as a respective low pressure chemical vapor deposition process). The first dielectric liner 632 and/or the second dielectric liner 634 may be employed as a respective etch stop dielectric layer and/or as a respective hydrogen diffusion barrier. In an illustrative example, the first dielectric liner 632 may comprise a silicon oxide liner having a thickness in a range from 4 nm to 30 nm, and the second dielectric liner 634 may comprise a silicon nitride liner having a thickness in a range from 4 nm to 30 nm, although lesser and greater thicknesses may also be employed for the first dielectric liner 632 and/or the second dielectric liner 634.

Referring to FIG. 2C, a planarizable dielectric material, such as undoped silicate glass or a doped silicate glass, can be deposited over the dielectric liners (632, 634). A chemical mechanical polishing process can be performed to remove portions of the planarizable dielectric material from above the horizontal plane including the topmost surfaces of the dielectric liners (632, 634). In one embodiment, the topmost surface of the second dielectric layer 634 may be employed as a stopping surface for the chemical mechanical polishing process. The remaining portion of the planarizable dielectric material constitutes a planarization dielectric layer 636 having a top surface located entirely within the horizontal plane including the topmost surface segments of the second dielectric liner 634. The set of all dielectric material layers located between the horizontal plane including the bottommost surfaces of the gate stack structures 650 and the horizontal plane including the topmost surfaces of the gate stack structures 650 constitute a gate-level dielectric layer 630. The horizontal plane including the bottommost surfaces of the gate stack structures 650 may contain the top surface of the substrate 9. The horizontal plane including the topmost surfaces of the gate stack structures 650 may be located underneath the top surface of the planarization dielectric layer 636. The gate-level dielectric layer 630 comprises the planarization dielectric layer 636, and may further comprise the first dielectric liner 632 and/or the second dielectric liner 634. The gate-level dielectric layer 630 may comprise a planar bottom surface located entirely within a horizontal plane including the top surface of a semiconductor material layer in the substrate 9 and a planar top surface located entirely within another horizontal plane including the topmost surface segments of the second dielectric liner 634.

Referring to FIG. 2D, a sacrificial dielectric layer 637 can be formed on the topmost surface of the gate-level dielectric layer 630. The sacrificial dielectric layer 637 may comprise undoped silicate glass, a doped silicate glass, or organosilicate glass. The sacrificial dielectric layer 637 may have a thickness in a range from 50 nm to 300 nm, such as from 100 nm to 200 nm, although lesser and greater thicknesses may also be employed.

Referring to FIG. 2E, a photoresist layer (not shown) can be applied to the planar top surface of the sacrificial dielectric layer 637, and can be lithographically patterned to form openings over a first subset of the active regions (622, 623). An anisotropic etch process can be performed to transfer the pattern of the openings in the photoresist layer through the sacrificial dielectric layer 637 and the gate-level dielectric layer 630. A terminal step of the anisotropic etch process may be selective to the semiconductor materials of the active regions (622, 623). In an illustrative example, the anisotropic etch process may comprise a first anisotropic etch step that etches the material of the sacrificial dielectric layer 637 and the planarization dielectric layer 636, a second anisotropic etch step that etches the material of the second dielectric liner 634 selective to the material of the first dielectric liner 632, and a third anisotropic etch step that etches the material of the first dielectric liner 632 selective to the materials of the active regions (622, 623). The photoresist layer can be subsequently removed, for example, by ashing.

Pedestal-contact via cavities 639 are formed in volumes from which the materials of sacrificial dielectric layer 637 and the gate-level dielectric layer 630 are removed by the anisotropic etch process. The pedestal-contact via cavities are formed over the first subset of the active regions (622, 623). The first subset of the active regions (622, 623) is exposed to the pedestal-contact via cavities 639.

Referring to FIG. 2F, a semiconductor material deposition process can be performed to deposit a semiconductor material in each of the pedestal-contact via cavities 639. In one embodiment, the semiconductor material deposition process may comprise a selective semiconductor deposition process that grows a semiconductor material from physically exposed semiconductor surfaces while suppressing growth of the semiconductor material from dielectric surfaces. In this case, the exemplary structure may be placed in a reactor configured to perform a selective semiconductor deposition process, and a semiconductor-containing reactant gas can be flowed concurrently with or alternately with an etchant gas. For example, a silicon-containing precursor gas such as silane or dichlorosilane can be flowed into the reactor concurrently with or alternately with gas phase hydrogen chloride. A carrier gas, such as hydrogen gas, helium gas, and/or nitrogen gas, may be employed during the selective semiconductor deposition process. In one embodiment, the selective semiconductor deposition process may be performed at a sufficiently high deposition temperature in an environment with sufficiently low partial pressure of residual impurity gases so that the deposited semiconductor material can be epitaxially aligned to an underlying semiconductor material. In this case, the selective semiconductor deposition process may be a selective epitaxy process.

Semiconductor pillar structures 640 can be formed in lower portions of the pedestal-contact via cavities 639. In one embodiment, the selective semiconductor deposition process comprises a selective epitaxy process, and the semiconductor pillar structures 640 may comprise single-crystalline semiconductor material portions, such as single crystal silicon portions. The semiconductor pillar structures 640 may be undoped (i.e., may not include any intentionally-introduced electrical dopants), or may be doped with p-type dopants or n-type dopants. Upper portions of the pedestal-contact via cavities 639 remain unfilled.

Referring to FIG. 2G, at least one masked ion implantation process may be performed to suitably dope the semiconductor pillar structures 640. For example, each semiconductor pillar structure 640 that overlies an n-doped active region 622 can be doped with n-type electrical dopants (e.g., phosphorus or arsenic). Each semiconductor pillar structure 640 that overlies a p-doped active region 623 can be doped with p-type electrical dopants (e.g., boron). Each semiconductor pillar structure 640 that is doped with the n-type electrical dopants constitutes an n-doped semiconductor pillar structure 642, such as n-type single crystal silicon structure. Each semiconductor pillar structure 640 that is doped with the p-type electrical dopants constitutes a p-doped semiconductor pillar structure 643, such as p-type single crystal silicon structure. The net atomic concentration of electrical dopants in the n-doped semiconductor pillar structures 642, or the p-doped semiconductor pillar structures 643, may be in a range from 1.0×10¹⁸/cm³ to 1.0×10²¹/cm³, although lesser and greater net atomic concentrations may also be employed.

Alternatively, the semiconductor material deposition process employed to form the semiconductor pillar structures 640 at the processing steps of FIG. 2F may deposit a doped semiconductor material having a doping of a first conductivity type, which may be p-type or n-type. The atomic concentration of dopants of the first conductivity type in the deposited semiconductor material may be in a range from 1.0×10¹⁸/cm³ to 1.0×10²¹/cm³, although lesser and greater net atomic concentrations may also be employed. In this case, a masked ion implantation process can be performed to implant dopants of a second conductivity type which is the opposite of the first conductivity type into a subset of the semiconductor pillar structures 640 at an implantation dose such that the implanted subset of the semiconductor pillar structures 640 are converted into semiconductor material portions having a net doping of the second conductivity type. The net dopant concentration of such implanted subsets of the semiconductor pillar structures 640, as calculated by the atomic concentration of dopants of the second conductivity type less the atomic concentration of dopants of the first conductivity type, may be in a range from 1.0×10¹⁸/cm³ to 1.0×10²¹/cm³, although lesser and greater net atomic concentrations may also be employed.

Referring to FIG. 2H, a photoresist layer (not shown) can be applied over the sacrificial dielectric layer 637, and can be lithographically patterned to form openings in areas that overlie additional electrical nodes of the field effect transistors. In one embodiment, the openings in the photoresist layer can be located over active regions (622, 623) and gate electrodes 654 of the field effect transistors. An anisotropic etch process can be performed to form via cavities through the sacrificial dielectric layer 637, the gate-level dielectric layer 630, and the gate cap dielectrics 658. Additional contact-level via cavities (651, 638) are formed through the sacrificial dielectric layer 637, the gate-level dielectric layer 630, and the gate cap dielectrics 658. The contact-level via cavities (651, 638, 639) comprise the pre-existing pedestal-contact via cavities 639, the newly formed active-region-contact via cavities 638, and the newly formed gate-contact via cavities 651. The pedestal-contact via cavities 639 are located over the semiconductor pedestal structures (642, 643) such that top surfaces of the semiconductor pedestal structures (642, 643) are exposed underneath the pedestal contact via cavities 639. The active-region-contact via cavities 638 are formed over the active regions (622, 623) such that top surfaces of the active regions (622, 623) are exposed underneath the active-region-contact via cavities 638. The gate-contact via cavities 651 are formed over the gate electrodes 654 such that top surfaces of the gate electrodes 654 are exposed underneath the gate-contact via cavities 637.

Referring to FIG. 2I, a metallic barrier liner layer and a metallic material layer can be sequentially deposited in the contact-level via cavities (651, 638, 639) and over the sacrificial dielectric layer 637. The metallic barrier liner layer comprises a metallic nitride material that is thermally stable in an elevated temperature range such as a temperature range from 800 degrees Celsius to 1,050 degrees Celsius that may be used to thermally activate doped semiconductor material portions during a subsequent anneal process to be employed during formation of a three-dimensional memory array. For example, the metallic barrier line layer may comprise, and/or may consist essentially of, WN, MoN, TiN, or TaN. The thickness of the metallic barrier liner layer may be in a range from 5 nm to 50 nm, although lesser and grater thicknesses may also be employed. Alternatively, the metallic barrier layer may be omitted.

The metallic material layer comprises a metal that is thermally stable in the elevated temperature range of the subsequent anneal process to be employed during formation of a three-dimensional memory array. In one embodiment, the metallic material layer comprises and/or consists essentially of a refractory metal having a melting temperature higher than 2,200 degrees Celsius, such as W, Mo or Ta. The thickness of the metallic material layer may be in a range from 30 nm to 200 nm, such as from 50 nm to 120 nm, although lesser and greater thicknesses may also be employed.

A first chemical mechanical planarization process can be performed to remove portions of the metallic barrier liner layer and the metallic material layer from above the horizontal plane including the top surface of the sacrificial dielectric layer 637. Each remaining contiguous portion of the metallic barrier liner layer and the metallic material layer filling a respective contact-level via cavity (651, 638, 639) constitutes a metallic contact via structure (647, 648, 646). The metallic contact via structures (647, 648, 646) comprise pedestal-contact via structures 646 that are formed in the pedestal-contact via cavities 639, active-region-contact via structures 648 that are formed in the active-region-contact via cavities 638, and gate-contact via structures 647 that are formed in the gate-contact via cavities 651.

Referring to FIG. 2J, a second chemical mechanical planarization process can be performed to remove the entirety of the sacrificial dielectric layer 637 and portions of the metallic barrier liner layer and the metallic material layer located above the horizontal plane including the bottom surface of the sacrificial dielectric layer 637. In one embodiment, the top surfaces of the gate cap dielectrics 658 can be employed as stopping structures for the second chemical mechanical planarization process. In this case, portions of the dielectric liners (632, 634) that overlie the horizontal plane including the top surfaces of the gate cap dielectrics 658 can be removed during the second chemical mechanical planarization process. Portions of the metallic contact via structures (647, 648, 646) that overlie the horizontal plane including the top surfaces of the gate cap dielectrics 658 can be removed during the second chemical mechanical planarization process. The metallic contact via structures (647, 648, 646) have top surfaces located within the horizontal plane including the top surface of the gate-level dielectric layer 630 after the second chemical mechanical planarization process. Thus, each of the pedestal-contact via structures 646, the active-region-contact via structures 648, and the gate-contact via structures 647 can have top surfaces located within the horizontal plane including the top surface of the gate-level dielectric layer 630 after the second chemical mechanical planarization process.

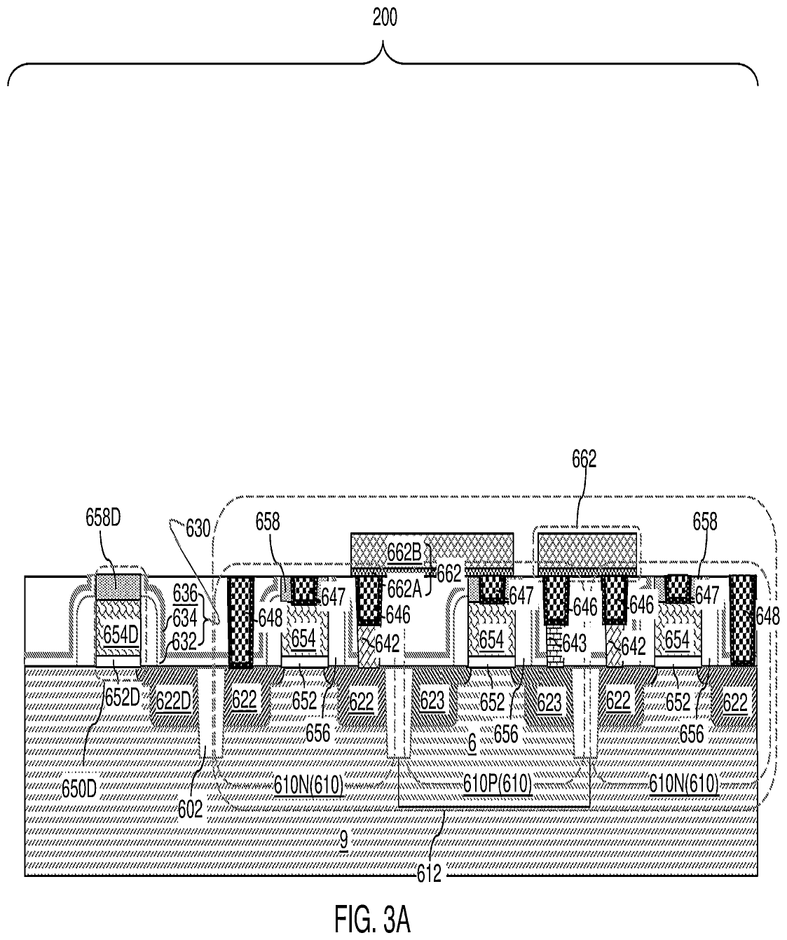

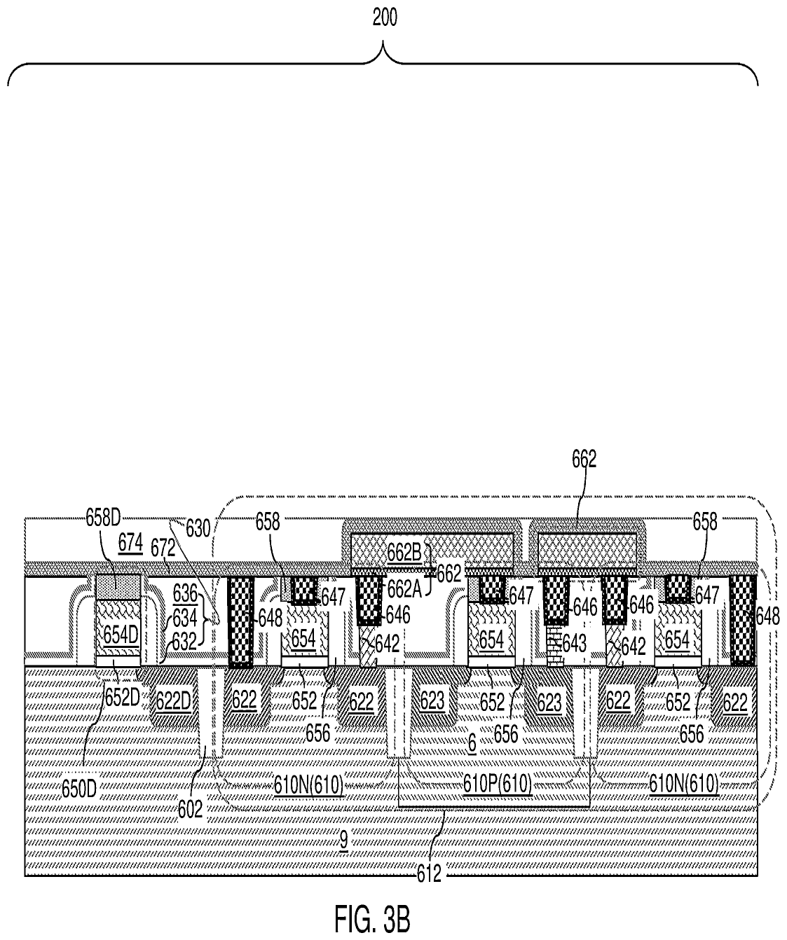

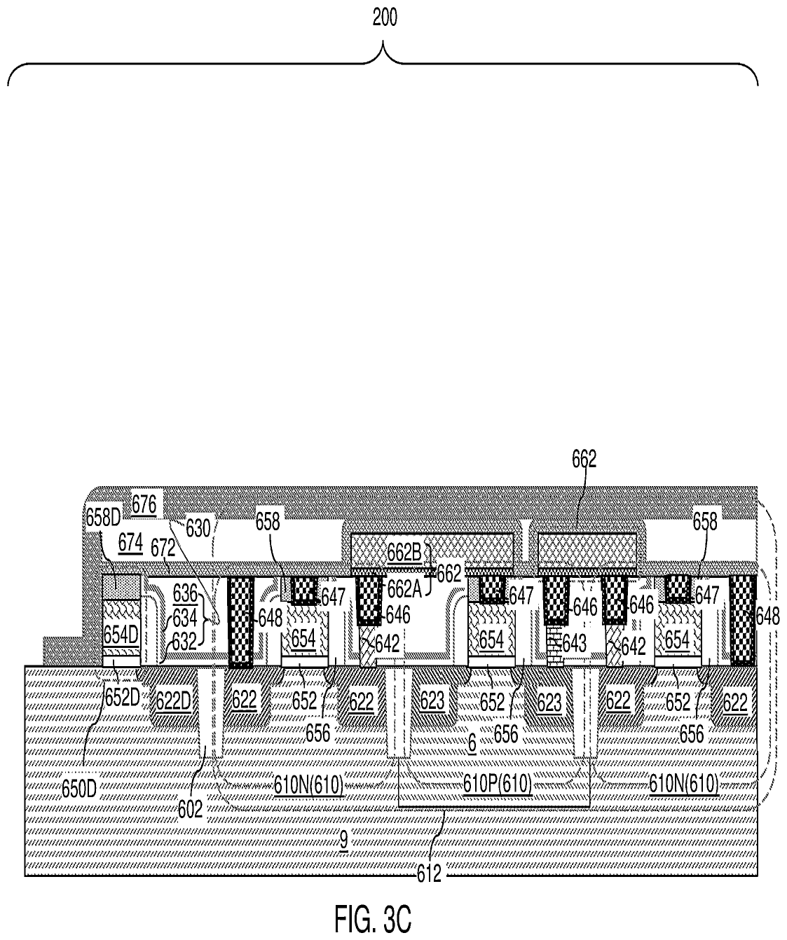

FIGS. 3A-3C are sequential vertical cross-sectional views of a portion of the peripheral region 200 of a first configuration of the exemplary structure during formation of metallic line structures 662 and capping-level dielectric layers (672, 674, 676) according to a first embodiment of the present disclosure.

Referring to FIG. 3A, a metallic barrier liner layer and a metallic material layer can be sequentially deposited on the top surfaces the metallic contact via structures (647, 648, 646) and on the top surface of the gate-level dielectric layer 630. The metallic barrier liner layer comprises a metallic nitride material that is thermally stable in an elevated temperature range such as a temperature range from 800 degrees Celsius to 1,050 degrees Celsius that may be used to thermally activate doped semiconductor material portions during a subsequent anneal process to be employed during formation of a three-dimensional memory array. For example, the metallic barrier line layer may comprise, and/or may consist essentially of, WN, MoN, TiN, or TaN. The thickness of the metallic barrier liner layer may be in a range from 5 nm to 50 nm, although lesser and grater thicknesses may also be employed. Alternatively, the metallic barrier layer may be omitted.

The metallic material layer comprises a metal that is thermally stable in the elevated temperature range of the subsequent anneal process to be employed during formation of a three-dimensional memory array. In one embodiment, the metallic material layer comprises and/or consists essentially of a refractory metal having a melting temperature higher than 2,200 degrees Celsius, such as W, Mo or Ta. The thickness of the metallic material layer may be in a range from 30 nm to 200 nm, such as from 50 nm to 120 nm, although lesser and greater thicknesses may also be employed.

A photoresist layer (not shown) can be applied over the metallic material layer, and can be lithographically patterned into discrete photoresist material portions. Each discrete photoresist material portion may cover a respective set of at least two metallic contact via structures (647, 648, 646). Generally, at least one of the patterned discrete photoresist material portions may continuously extend over areas of a respective set of at least two metallic contact via structures (647, 648, 646) which will be subsequently electrically connected to each other. An anisotropic etch process can be performed to etch portions of the metallic material layer and the metallic barrier liner layer (if present) that are not covered by the patterned portions of the photoresist layer. The anisotropic etch process may comprise a first anisotropic etch step that etches the material of the metallic material layer selective to the material of the metallic barrier liner layer, and a second anisotropic etch step that etches the material of the metallic barrier liner layer selective to the materials of the gate-level dielectric layer 630. Each continuous set of patterned portions of the metallic material layer and the metallic barrier liner layer comprises a metallic line structure 662. The photoresist layer can be subsequently removed, for example, by ashing.

Each metallic line structure 662 may comprise an optional metallic barrier liner 662A that is a patterned portion of the metallic barrier liner layer, and a metallic material portion 662B that is a patterned portion of the metallic material layer. Each metallic barrier liner 662A can be in contact with top surfaces of the metallic contact via structures (647, 648, 646). Each metallic material portion 662B overlies and contacts the top surface of a respective metallic barrier liner 662A. Within each metallic line structure 662 including a metallic barrier liner 662A and a metallic material portion 662B, sidewalls of the metallic material portion 662B can be vertically coincident with sidewalls of the metallic barrier liner 662A.

Each metallic line structure 662 is an electrically conductive structure. In one embodiment, one of the metallic line structures 662 may contact a top surface of a respective first metallic contact via structures (647, 648, 646), and may contact the top surface of a second metallic contact via structures (647, 648, 646). Each of the first metallic contact via structures (647, 648, 646) and the second metallic contact via structures (647, 648, 646) may independently be one of the pedestal-contact via structures 646, the active-region-contact via structures 648, and the gate-contact via structures 647. Each contiguous combination of a first semiconductor pillar structure (642 or 643), an optional second semiconductor pillar structure (642 or 643), at least one metallic contact via structures (647, 648, 646), and a metallic line structure 662 constitutes a local interconnect structure (642, 643, 646, 647, 662).

In one embodiment, a first field effect transistor 610 and a second field effect transistor 610 can be interconnected to each other through the local interconnect structures (642, 643, 646, 647, 662). For example, the first field effect transistor 610 may comprise a p-type field effect transistor 610P and the second field effect transistor 610 may comprise an n-type field effect transistor 610N, or vice versa. Alternatively, the first field effect transistor 610 and the second field effect transistor 610 may comprise two p-type field effect transistors 610P or two n-type field effect transistors 610N. In one embodiment, a first local interconnect structure (642, 643, 646, 662) comprises a first semiconductor pillar structure (642 or 643) contacting a top surface of an active region (622, 623) of a first field effect transistor 610, a first pedestal-contact via structures 646, a metallic structure (e.g., the metallic line structure 662) contacting a top surface of the first pedestal-contact via structures 646, a second pedestal-contact via structures 646 contacting a bottom surface of the metallic structure, and a second semiconductor pillar structure (642, 643) contacting an electrical node (622, 623, or 654) of a second field effect transistor 610 and contacting a bottom surface of the second pedestal-contact via structure 646. The electrical node of the second field effect transistor 610P may comprise an active region (622 or 623) of the second field effect transistor 610, or a gate electrode 654 of the second field effect transistor 610.

In summary, at least a first field effect transistor 610 (e.g., 610N) and a second field effect transistor 610 (e.g., 610P) can be formed over a substrate 9. The first field effect transistor 610 comprises a first gate stack structure 650 including a first gate dielectric 652, a first gate electrode 654, and a first gate cap dielectric 658. The second field effect transistor 610 comprises a second gate stack structure 650 including a second gate dielectric 652, a second gate electrode 654, and a second gate cap dielectric 658. A gate-level dielectric layer 630 is formed around the gate stack structures 650 such that the top surface of the gate-level dielectric layer 630 is formed within the horizontal plane including the topmost surfaces of the gate stack structures 650. Semiconductor pillar structures (642, 643) are formed at a lower level of the gate-level dielectric layer 630. The metallic contact via structures (647, 648, 646) are formed at an upper-level of the gate-level dielectric layer 630 or through a respective one of the gate cap dielectrics 658.

If a local interconnect structure (642, 643, 646, 662) comprises a first pedestal-contact via structures 646 and a second pedestal-contact via structures 646, the top surface of the first pedestal-contact via structures 646 and the top surface of the second pedestal-contact via structures 646 may be located within a horizontal plane including a top surface of the first gate cap dielectric 658. If a local interconnect structure (642, 643, 646, 662) comprises a first pedestal-contact via structures 646 and a gate-contact via structures 647, the top surface of the first pedestal-contact via structures 646 and the top surface of the gate-contact via structures 647 may be located within a horizontal plane including a top surface of the first gate cap dielectric 658.

In one embodiment, the first semiconductor pillar structure (642 or 643) consists essentially of a first doped semiconductor material; and the second semiconductor pillar structure (642, 643) consists essentially of a second doped semiconductor material having a same semiconductor material composition as the first semiconductor pillar structure (642 or 643). As used herein, a “semiconductor composition” of a semiconductor material refers to the material composition of the semiconductor material that excludes all electrical dopants, i.e., all p-type dopants and all n-type dopants. For example, both structures may consist essentially of silicon having the same or different dopants. The semiconductor pillar structures (642, 643) are formed by a same semiconductor deposition process. Thus, the semiconductor composition of the semiconductor pillar structures (642, 643) is the same irrespective of electrical dopants that are incorporated into the semiconductor pillar structures (642, 643) during deposition or during subsequent implantation processes.

In one embodiment, the second semiconductor pillar structure (642, 643) is formed directly on a top surface of an active region (622, 623) of the second field effect transistor 610 and comprises a single-crystalline semiconductor material, such as single crystal silicon, in epitaxial alignment with a single-crystalline material in the active region (622, 623) of the second field effect transistor 610. In one embodiment, the first semiconductor pillar structure (642 or 643) may consists of a first single-crystalline semiconductor material, such as single crystal silicon, which is in epitaxial alignment with a single-crystalline material in an underlying active region (622, 623) of the first field effect transistor 610.

In one embodiment, the electrical node of the second field effect transistor 610 comprises an active region (622, 623) of the second field effect transistor 610; and the second semiconductor pillar structure (such as the semiconductor pillar structure (642, 643)) consists of a second single-crystalline semiconductor material that is in epitaxial alignment with a single-crystalline material in the active region (622, 623) of the second field effect transistor 610. In one embodiment, the first single-crystalline semiconductor material has a doping of a first conductivity type (which may be p-type or n-type); and the second single-crystalline semiconductor material portion has a doping of a second conductivity type (which may be n-type or p-type) that is an opposite of the first conductivity type. In an illustrative example, the peripheral circuit 612 may comprise a CMOS inverter circuit in which a p-doped active region 623 of a p-type field effect transistor 610P is electrically connected to an n-doped active region 622 of an n-type field effect transistor 610N. In this case, a local interconnect structure may comprise a combination of an n-doped semiconductor pillar structure 642 having an n-type doping (and optionally epitaxially aligned to an underlying n-doped active region 622), a first pedestal-contact via structure 646, a p-doped semiconductor pillar structure 643 having a p-type doping (and optionally epitaxially aligned to an underlying p-doped active region 631), a second pedestal-contact via structure 646, and a metallic structure (such as the metallic line structure 662) contacting a top surface of the first pedestal-contact via structure 646 and contacting a top surface of the second pedestal-contact via structure 646.

In another embodiment, the electrical node of the second field effect transistor 610 may comprise a gate electrode 654 of the second field effect transistor 610. In this case, gate-contact via structure 647 is formed through a gate cap dielectric 658 of the second field effect transistor 610, and contacts the gate electrode 654 of the second field effect transistor 610.

Referring to FIG. 3B, a dielectric passivation layer 672 can be formed on the topmost surface of the gate-level dielectric layer 630 and on the physically exposed surfaces of the metallic line structures 662. The dielectric passivation layer 672 comprises a hydrogen diffusion-blocking dielectric material, such as silicon nitride or silicon carbonitride. The dielectric passivation layer 672 can be deposited by a conformal deposition process, such as a chemical vapor deposition process. The thickness of the dielectric passivation layer 672 may be in a range from 30 nm to 100 nm, although lesser and greater thicknesses may also be employed.

A capping-level planarization dielectric layer 674 may be deposited over the dielectric passivation layer 672. The capping-level planarization dielectric layer 674 comprises a planarizable dielectric material, such as undoped silicate glass or a doped silicate glass. A planarization process, such as a chemical mechanical polishing process can be performed to remove portions of the capping-level planarization dielectric layer 674 from above the horizontal plane including the topmost surface of the dielectric passivation layer 672. The top surface of the capping-level planarization dielectric layer 674 may be formed within the horizontal plane including the topmost surface of the dielectric passivation layer 672.

Referring to FIG. 3C, a first photoresist layer (not shown) can be applied over the exemplary structure, and can be lithographically patterned to cover the peripheral region 200 without covering the memory array region 100 or the contact region 300. In one embodiment, an edge of the patterned photoresist layer may overlie the dummy gate stack structure 650D. An anisotropic etch process can be performed to remove unmasked portions of various structures of the exemplary structure that overlie the horizontal plane including the top surface of the substrate 9. The first photoresist layer can be subsequently removed, for example, by ashing.

A passivation capping layer 676 can be conformally deposited over remaining portions of the capping-level planarization dielectric layer 674 and the dielectric passivation layer 672, and on the physically exposed top surface of the substrate 9 in the memory array region 100 and in the contact region 300. The passivation capping layer 676 comprises a dielectric passivation material, such as silicon nitride or silicon carbonitride. Thus, the passivation capping layer 676 is a dielectric passivation layer. The passivation capping layer 676 can be deposited by a conformal deposition process, such as a chemical vapor deposition process. The thickness of the passivation capping layer 676 may be in a range from 50 nm to 200 nm, although lesser and greater thicknesses may also be employed.

A second photoresist layer (not shown) can be applied over the passivation capping layer 676, and can be lithographically patterned to cover the entire area of the gate-level dielectric layer 630 and vertically-extending portions of the passivation capping layer 676 that are proximal to the boundary between the peripheral region 200 and the contact region 300. An etch process, such as a wet etch process, can be performed to remove unmasked portions of the passivation capping layer 676. The second photoresist layer can be subsequently removed, for example, by ashing.

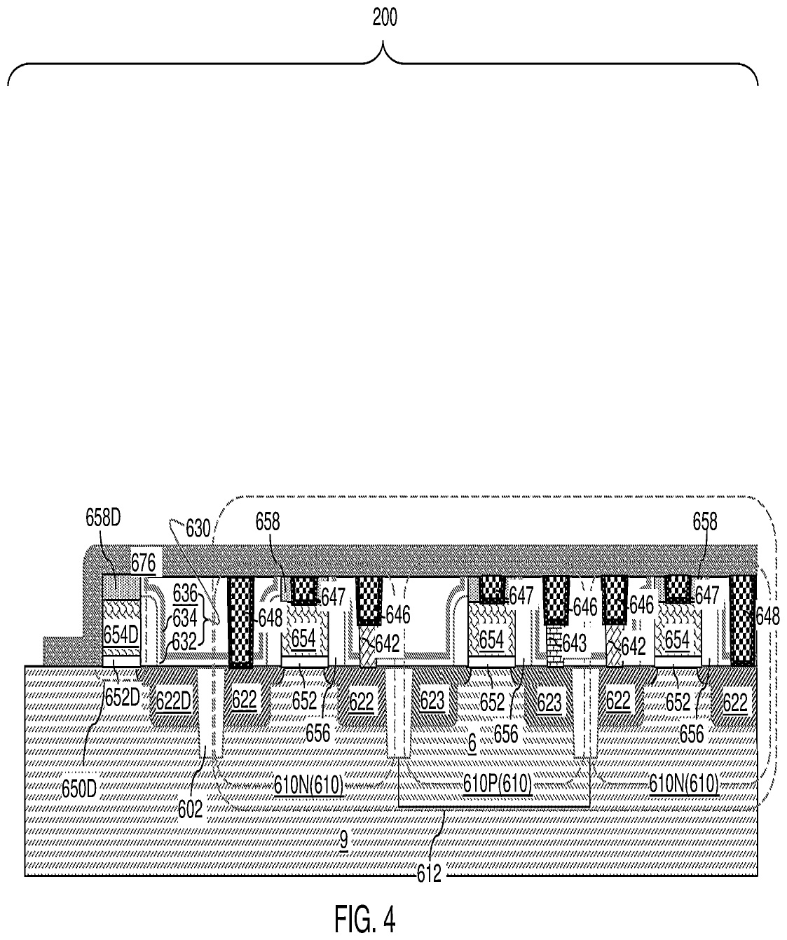

Referring to FIG. 4, a second configuration of the exemplary structure of the second embodiment can be derived from the exemplary structure illustrated in FIG. 2G by omitting the processing steps described with reference to FIGS. 3A and 3B and by performing the processing steps described with reference to FIG. 3C. Specifically, a first photoresist layer (not shown) can be applied over the exemplary structure illustrated with reference to FIG. 2G, and can be lithographically patterned to cover the peripheral region 200 without covering the memory array region 100 or the contact region 300. In one embodiment, an edge of the patterned photoresist layer may overlie the dummy gate stack structure 650D. An anisotropic etch process can be performed to remove unmasked portions of various structures of the exemplary structure that overlie the horizontal plane including the top surface of the substrate 9. The first photoresist layer can be subsequently removed, for example, by ashing.

The passivation capping layer 676 can be conformally deposited over remaining portions of the gate-level dielectric layer 630, and on the physically exposed top surface of the substrate 9 in the memory array region 100 and in the contact region 300.

A second photoresist layer (not shown) can be applied over the passivation capping layer 676, and can be lithographically patterned to cover the entire area of the gate-level dielectric layer 630 and vertically-extending portions of the passivation capping layer 676 that are proximal to the boundary between the peripheral region 200 and the contact region 300. An etch process, such as a wet etch process, can be performed to remove unmasked portions of the passivation capping layer 676. The second photoresist layer can be subsequently removed, for example, by ashing.

In case the second configuration of the exemplary structure of FIG. 4 is formed, the metallic line structure 662 of FIG. 3B is omitted. Instead, metallic structures providing electrical connection within a respective set of at least two metallic contact via structures (647, 648, 646) are formed in a subsequent processing step to be described below.

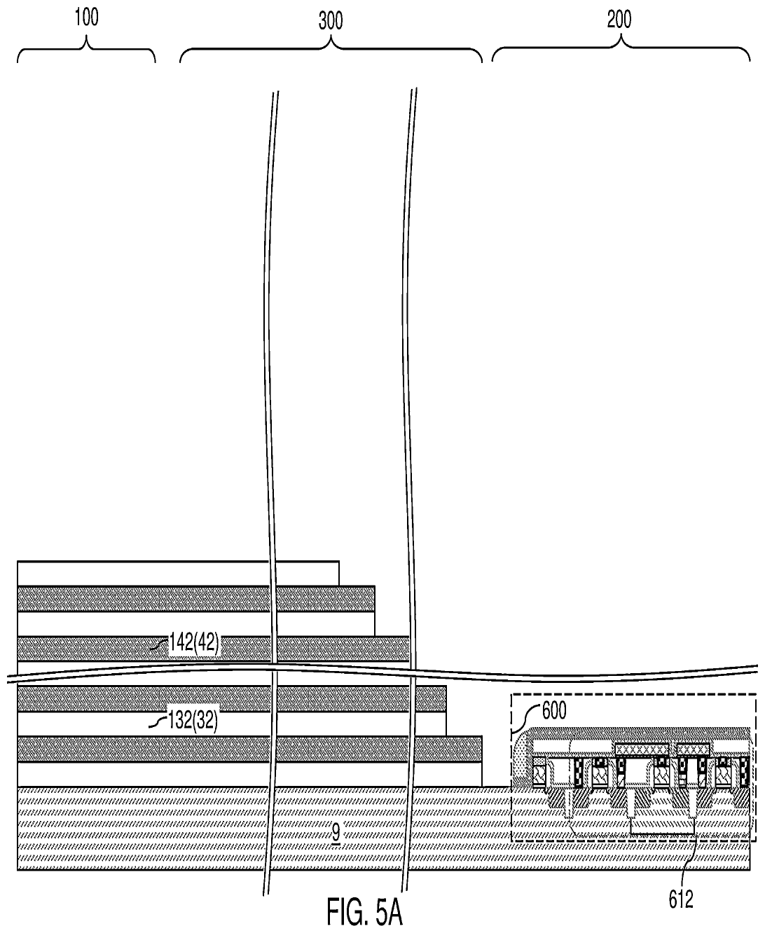

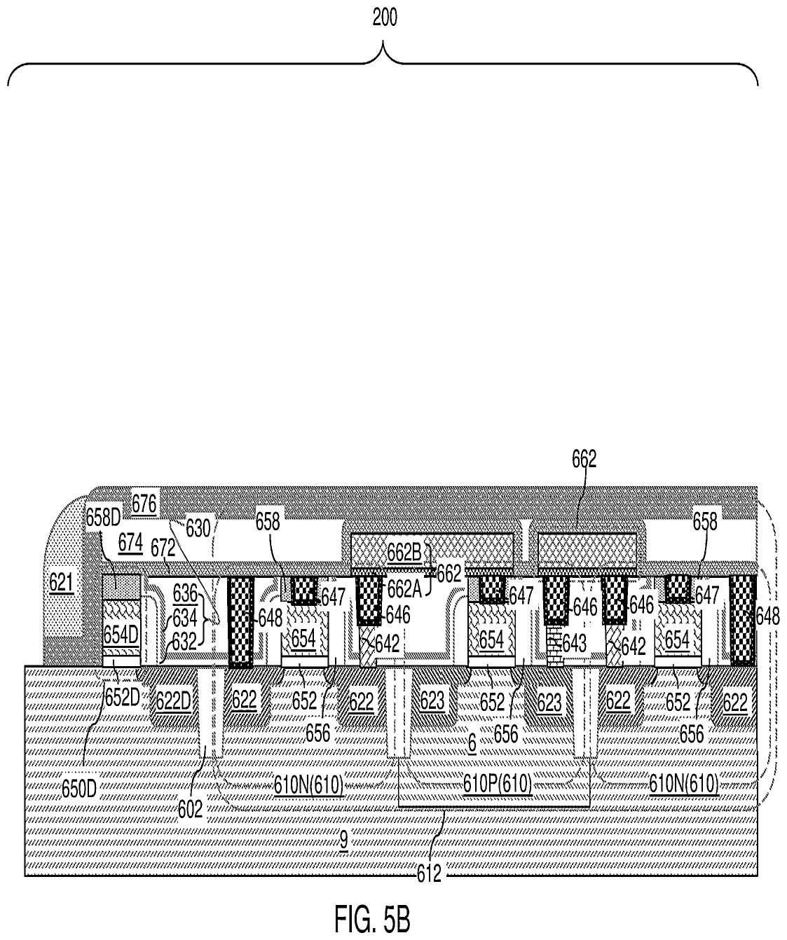

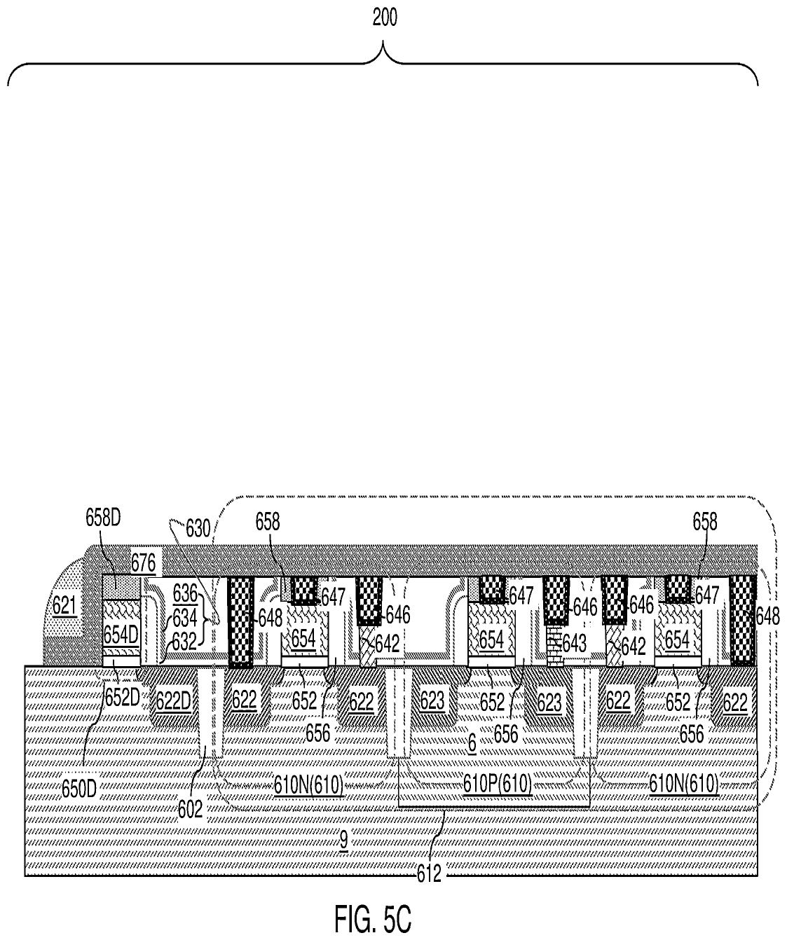

FIG. 5A is a vertical cross-sectional view of the exemplary structure after deposition and patterning of a first alternating stack (132, 142) of first insulating layers 132 and first sacrificial material layers 142 over the structure of the first or second embodiments of FIG. 3C or FIG. 4, respectively. FIG. 5B is a magnified view of a portion of a peripheral region 200 in the first configuration of the exemplary structure of the first embodiment after the processing steps of FIG. 5A. FIG. 5C is a magnified view of a portion of a peripheral region 200 in the second configuration of the exemplary structure of the second embodiment after the processing steps of FIG. 5A.

Referring collectively to FIGS. 5A-5C, a first alternating stack of first insulating layers 132 and first spacer material layers can be formed over the substrate 9. In one embodiment, the first spacer material layers may comprise first sacrificial material layers 142. In this case, a first alternating stack (132, 142) of first insulating layers 132 and first sacrificial material layers 142 can be formed over the substrate 9. The first insulating layers 132 are a first subset of insulating layer 32 employed to form a three-dimensional memory array, and the second sacrificial material layers are a first subset of sacrificial material layers 42 employed to form the three-dimensional memory array. The first insulating layers 132 comprise an insulating material, such as undoped silicate glass (i.e., silicon oxide) or a doped silicate glass, and the first sacrificial material layers 142 comprise a sacrificial material, such as silicon nitride. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed.

The first alternating stack (132, 142) are patterned such that the first alternating stack (132, 142) is removed from the peripheral region 200, is not removed from the memory array region 100, and is partially removed from the contact region 300 such that first stepped surfaces of the first alternating stack (132, 142) are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) are removed upon formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from a bottommost layer within the first alternating stack (132, 142) to the topmost layer within the first alternating stack (132, 142).

Generally, removal of the portions of the first alternating stack (132, 142) from the peripheral region 200 may be performed in a manner that does not remove the passivation capping layer 676. Optionally, a suitable masking scheme may be employed to ensure that the passivation capping layer 676 is not etched through during removal of the portions of the first alternating stack (132, 142) from the peripheral region 200. In some embodiments, a residual material portion 621 that comprises residual remaining portions of the first alternating stack (132, 142) may be formed on an outer sidewall of the passivation capping layer 676. The residual material portion 621 may comprise remaining portions of the first insulating layers 132 and remaining portions of the first sacrificial material layers 142. The peripheral circuit 612 can be protected from subsequent processing steps by the passivation capping layer 676. As such, the passivation capping layer 676 and structural elements underlying the passivation capping layer 676 are herein referred to as passivation encapsulated structures 600.

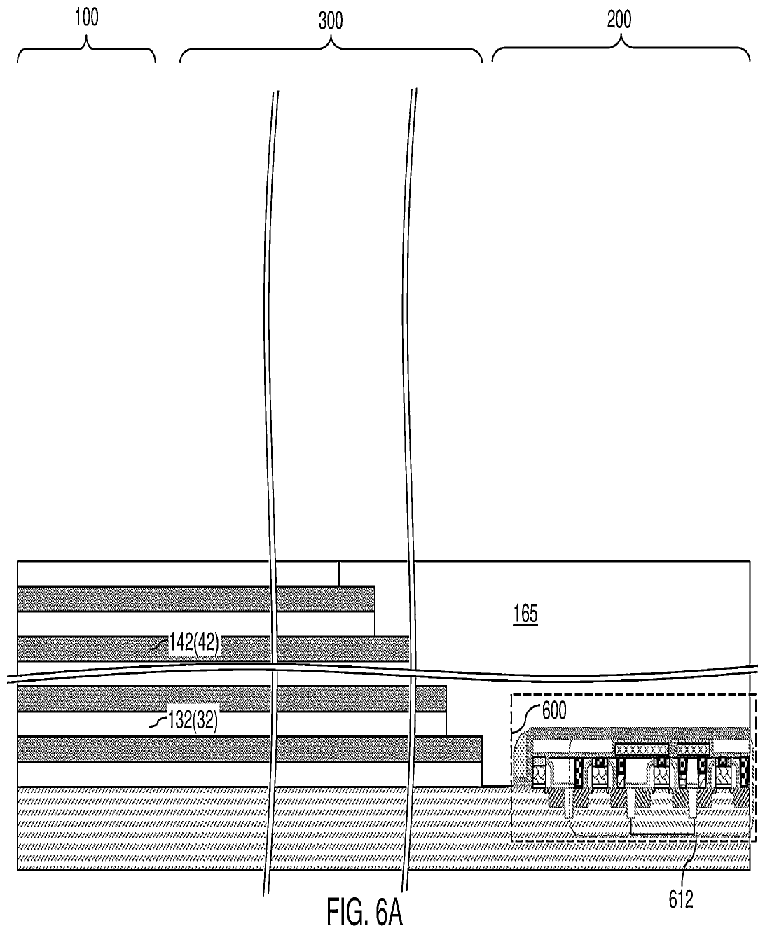

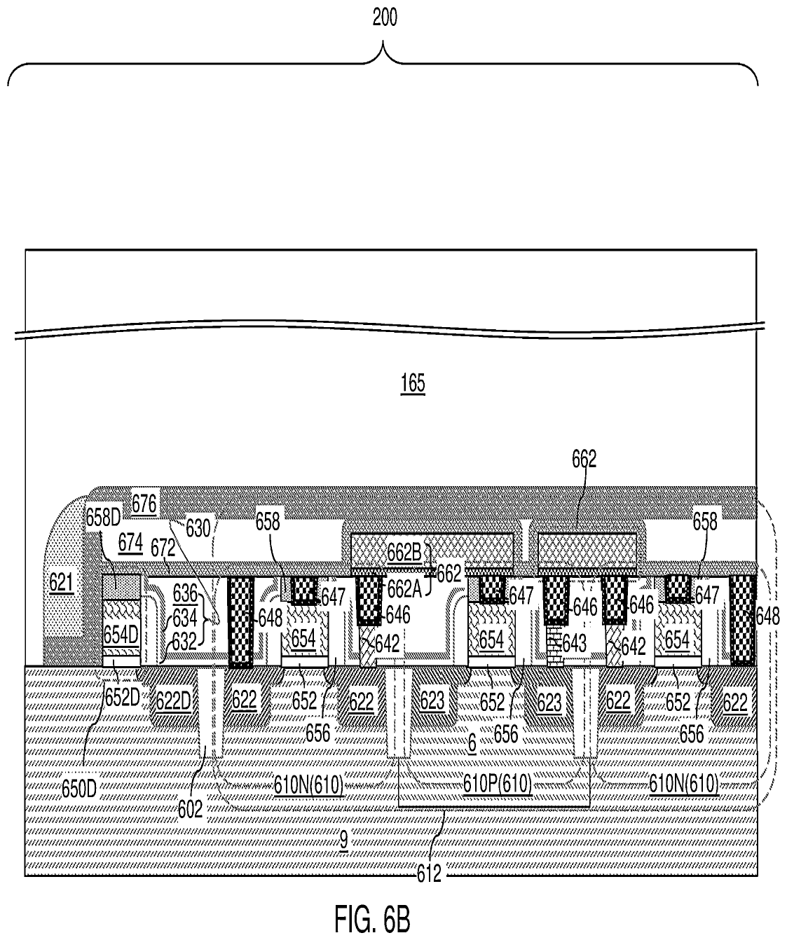

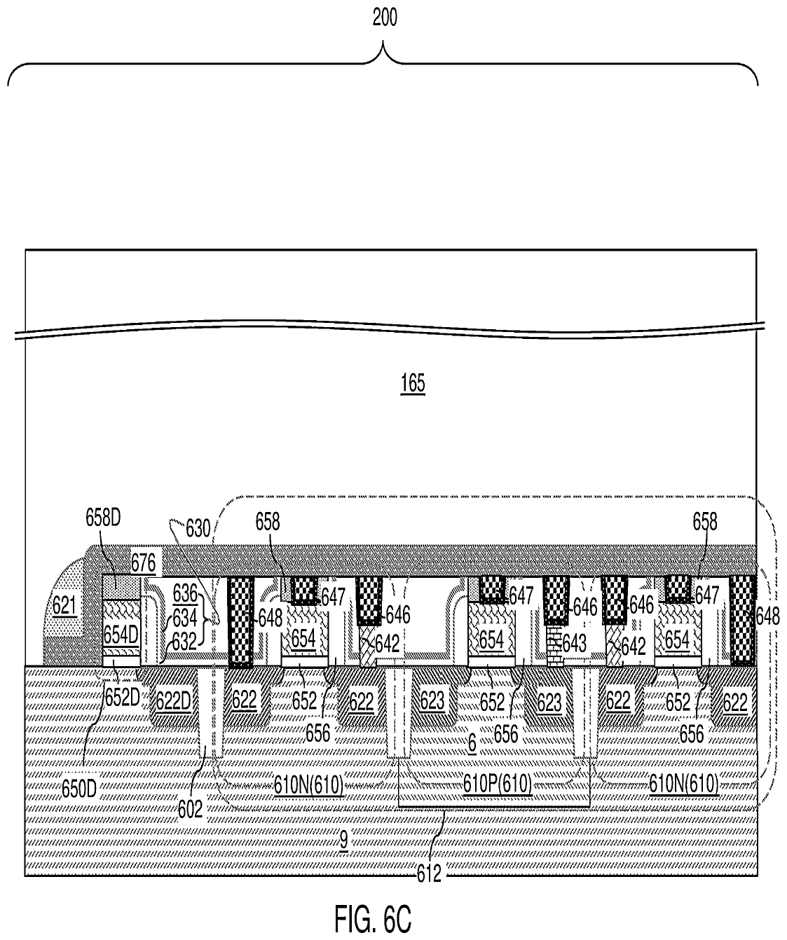

FIG. 6A is a vertical cross-sectional view of the exemplary structure after formation of a first retro-stepped dielectric material portion (such as a first retro-stepped dielectric material portion 165) according to an embodiment of the present disclosure. FIG. 6B is a magnified view of a portion of a peripheral region 200 in the first configuration of the exemplary structure of the first embodiment after the processing steps of FIG. 6A. FIG. 6C is a magnified view of a portion of a peripheral region 200 in the second configuration of the exemplary structure of the second embodiment after the processing steps of FIG. 6A.

Referring collectively to FIGS. 6A-6C, a first retro-stepped dielectric material portion 165 (i.e., an insulating fill material portion) can be formed in the first stepped cavity by deposition of a dielectric material therein. For example, a dielectric material such as silicon oxide can be deposited in the first stepped cavity. Excess portions of the deposited dielectric material can be removed from above the top surface of the topmost first insulating layer 132, for example, by chemical mechanical planarization (CMP). The remaining portion of the deposited dielectric material filling the first stepped cavity constitutes the first retro-stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first retro-stepped dielectric material portion 165, the silicon oxide of the first retro-stepped dielectric material portion 165 may, or may not, be doped with dopants such as B, P, and/or F. In one embodiment, the first retro-stepped dielectric material portion 165 overlies and contacts the first stepped surfaces, and has a top surface that is coplanar with the top surface of the topmost first insulating layer 132. The top surface of the first retro-stepped dielectric material portion 165 may be formed within the horizontal plane including the topmost layer of the first alternating stack (132, 142) such as a topmost first insulating layer 132.

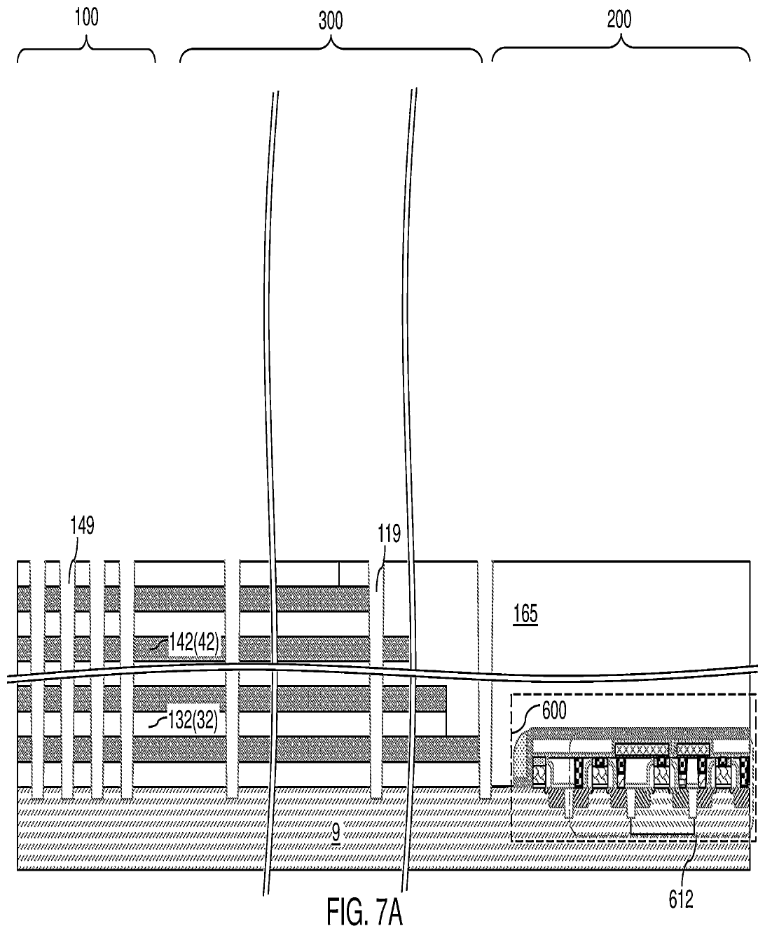

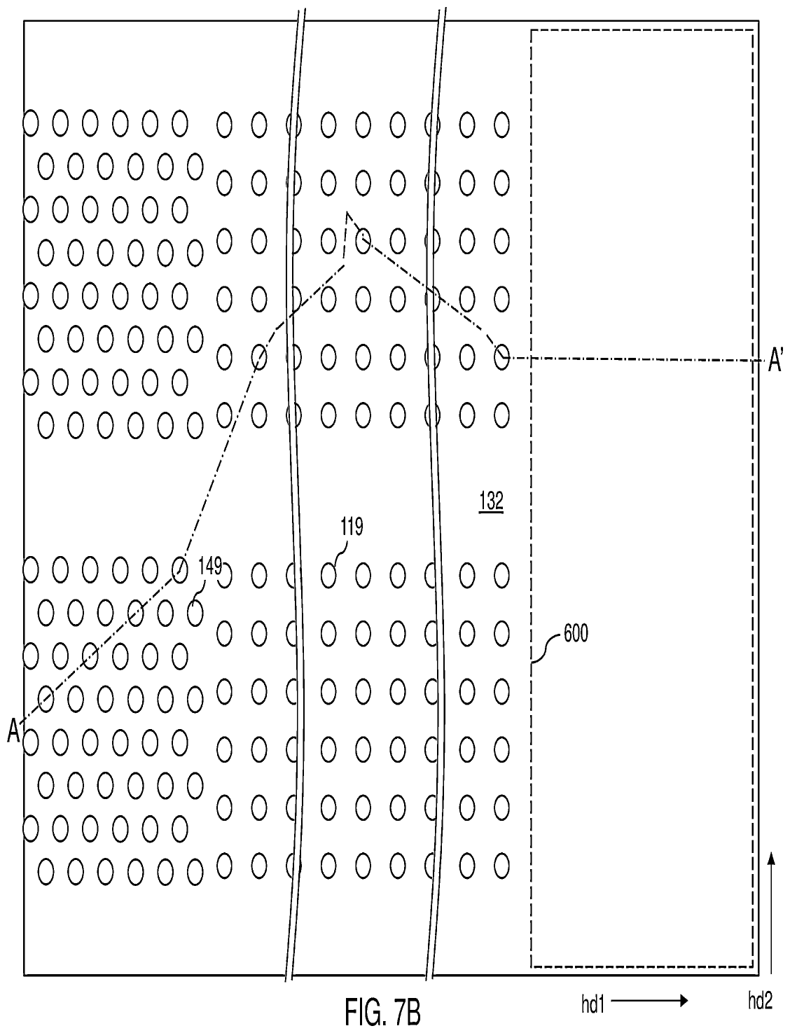

Referring to FIGS. 7A and 7B, a first etch mask layer (not shown) can be formed over the first alternating stack (132, 142), and can be lithographically patterned to form various openings therein. A first anisotropic etch process can be performed to transfer the pattern of the openings in the first etch mask layer through the first alternating stack (132, 142) and the portion of the first retro-stepped dielectric material portion 165 in the contact region 300. Various openings can be formed through the first alternating stack (132, 142) and the first retro-stepped dielectric material portion 165. The various openings may comprise first-tier memory openings 149 that are formed in the memory array region 100 and first-tier support openings 129 that are formed in the contact region 300. Each of the first-tier memory openings 149 and the first-tier support openings 129 can vertically extend through the first alternating stack (132, 142) into a top portion of the substrate 9. In one embodiment, bottom surfaces of the first-tier memory openings 149 and the first-tier support openings 129 may comprise recessed surfaces of the substrate 9. The depth of the bottom surfaces of the first-tier memory openings 149 and the first-tier support openings 129 as measured from the horizontal plane including the top surface of the substrate 9 may be in a range from 1 nm to 50 nm, although lesser and greater depths may also be employed.

The first-tier support openings 129 may have a maximum diameter in a range from 50 nm to 400 nm, such as from 70 nm to 300 nm, although lesser and greater maximum diameters may be employed. The first-tier memory openings 149 may have a maximum diameter in a range from 50 nm to 400 nm, such as from 70 nm to 300 nm, although lesser and greater maximum diameters may be employed.

In one embodiment, the memory array region 100 may be laterally spaced apart from the contact region 300 along a first horizontal direction hd1. The first-tier memory openings 149 may comprise rows of first-tier memory openings 149 that are arranged along the first horizontal direction hd1 and laterally spaced apart along a second horizontal direction hd2 that is perpendicular to the first horizontal direction hd2. Multiple clusters of first-tier memory openings 149, each containing a respective two-dimensional periodic array of first-tier memory openings 149, may be formed in the memory array region 100. The clusters of first-tier memory openings 149 may be laterally spaced apart along the second horizontal direction hd2.

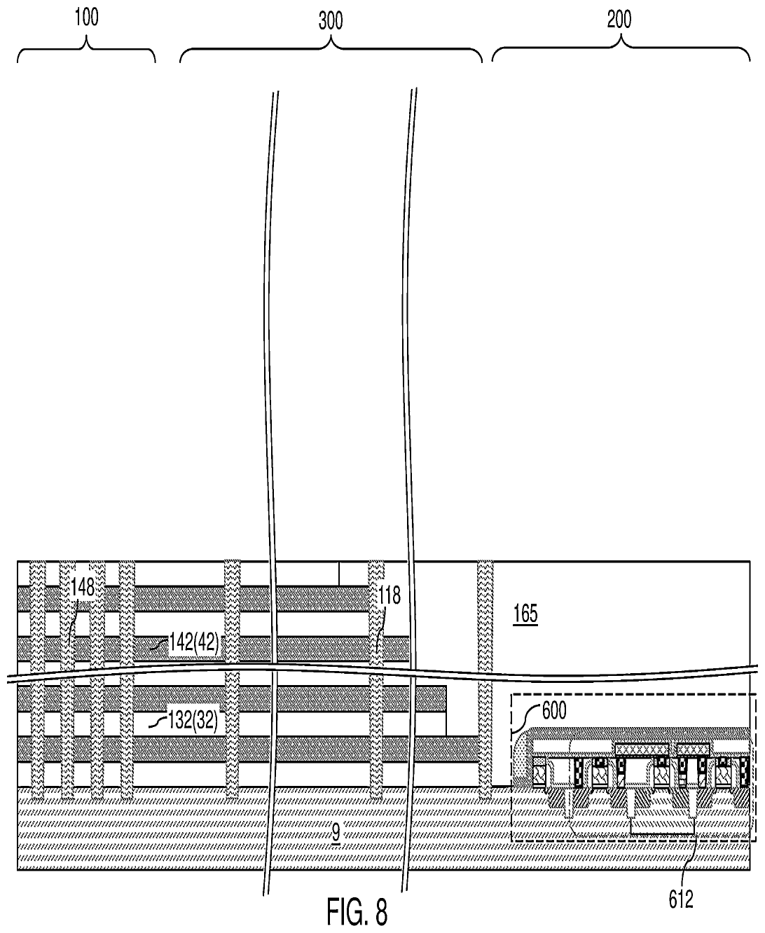

Referring to FIG. 8, a first sacrificial fill material can be deposited in the first-tier memory openings 149 and the first-tier support openings 119. The first sacrificial fill material may comprise a semiconductor material (such as amorphous silicon, polysilicon, a silicon-germanium alloy, etc.), a carbon-based material including carbon atoms at an atomic percentage greater than 80% (such as amorphous carbon or diamond-like carbon), or a polymer material.

A planarization process can be performed to remove portions of the first sacrificial fill material from above the horizontal plane including the top surface of the first-tier alternating stack (132, 142). The planarization process can be stopped such that each remaining portion of the first sacrificial fill material has a top surface at, or about, a horizontal plane including the top surface of the first-tier alternating stack (132, 142). The planarization process may comprise a recess etch process and/or a chemical mechanical polishing process. Remaining portions of the first sacrificial fill material that fill the first-tier memory openings 149 and the first-tier support openings 119 constitute first-tier sacrificial opening fill structures (148, 118). The first-tier sacrificial opening fill structures (148, 118) comprise first-tier sacrificial memory opening fill structures 148 that are formed in the first-tier memory openings 149, and first-tier sacrificial support opening fill structures 118 that are formed in the first-tier support openings 119.

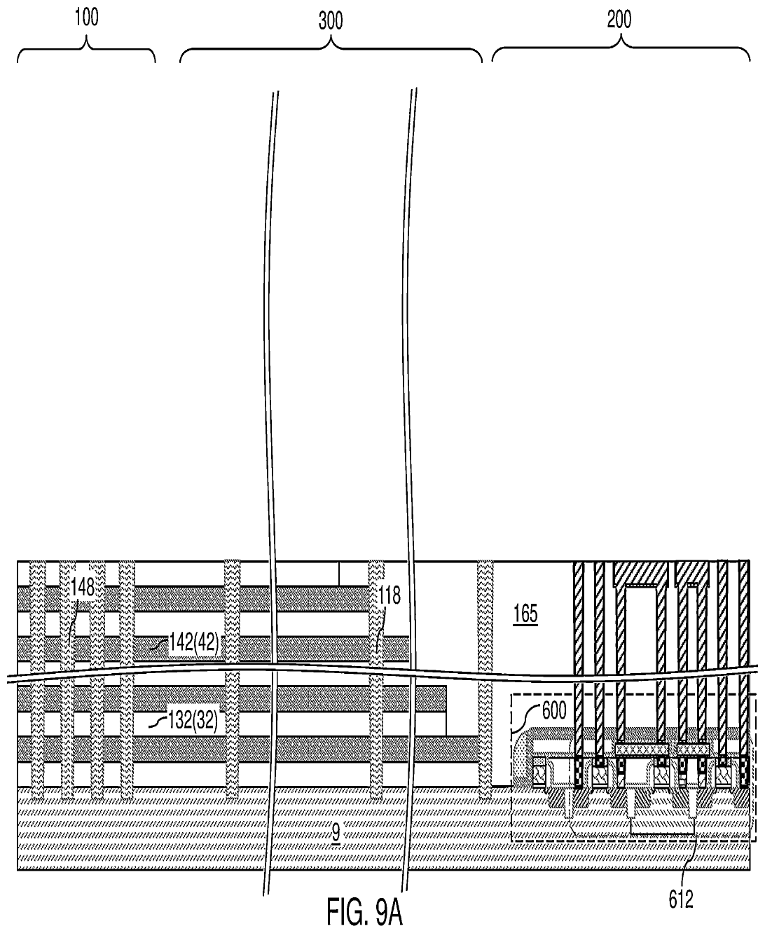

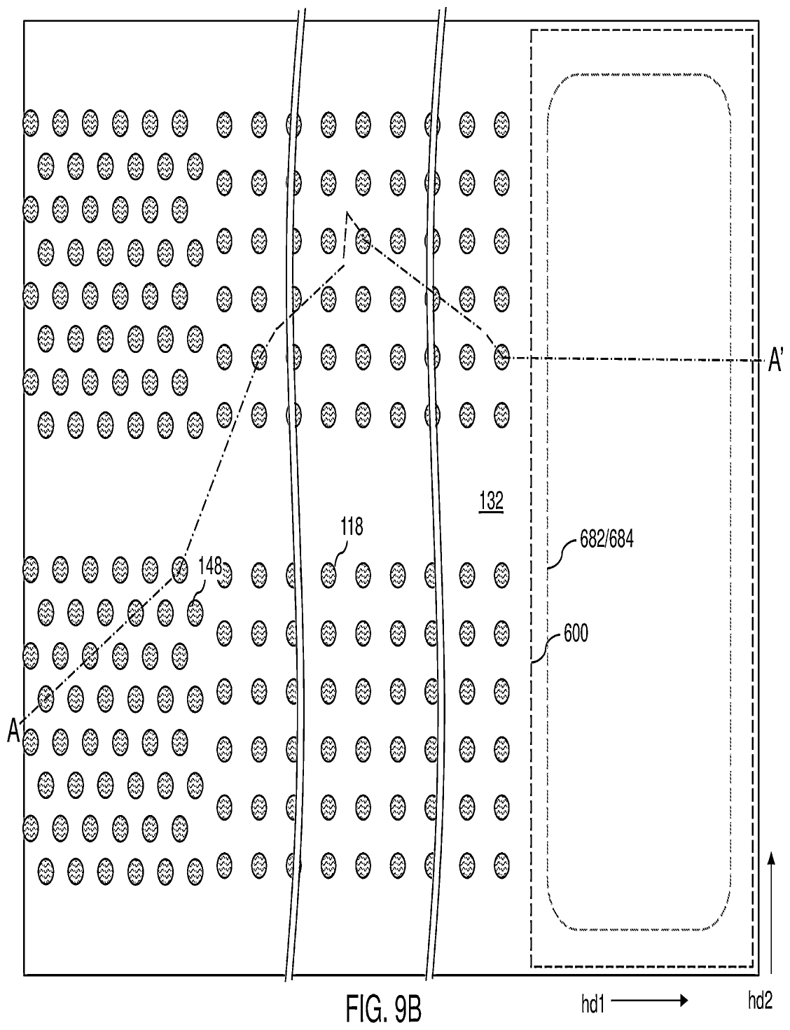

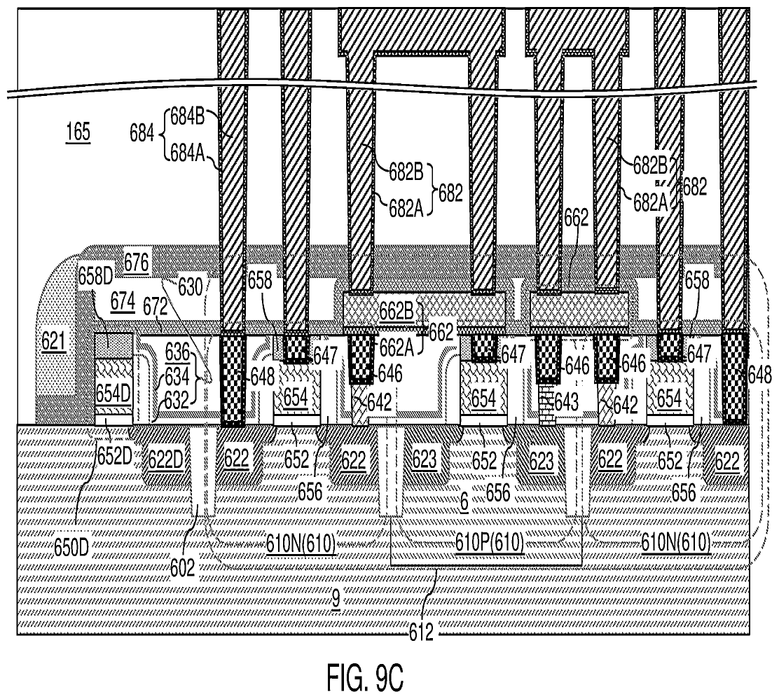

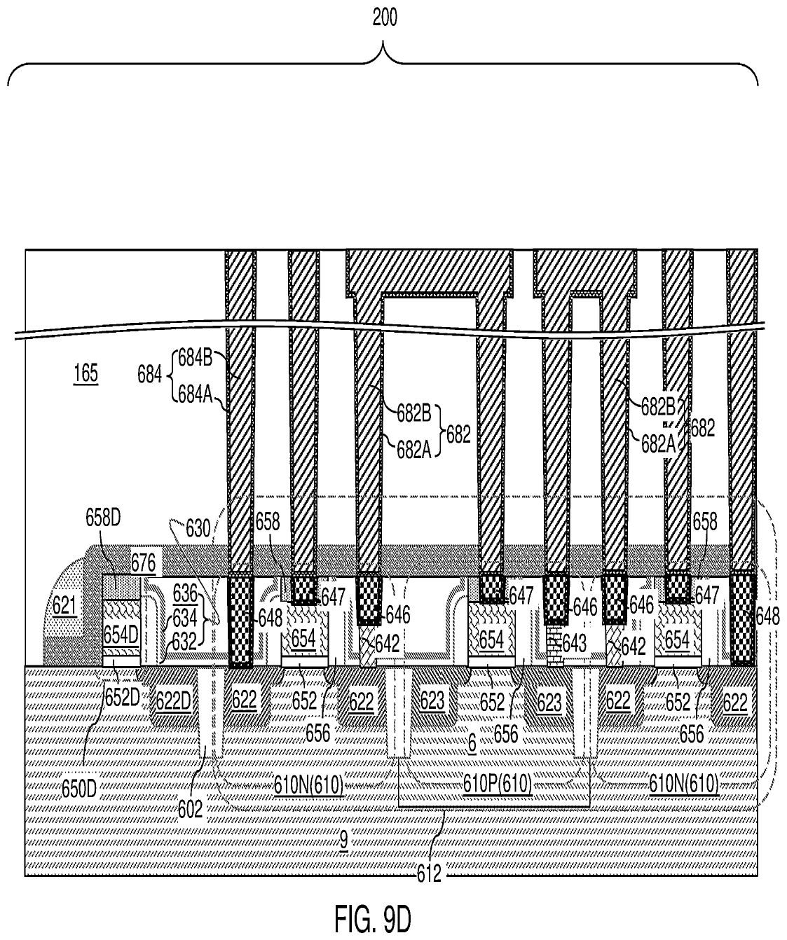

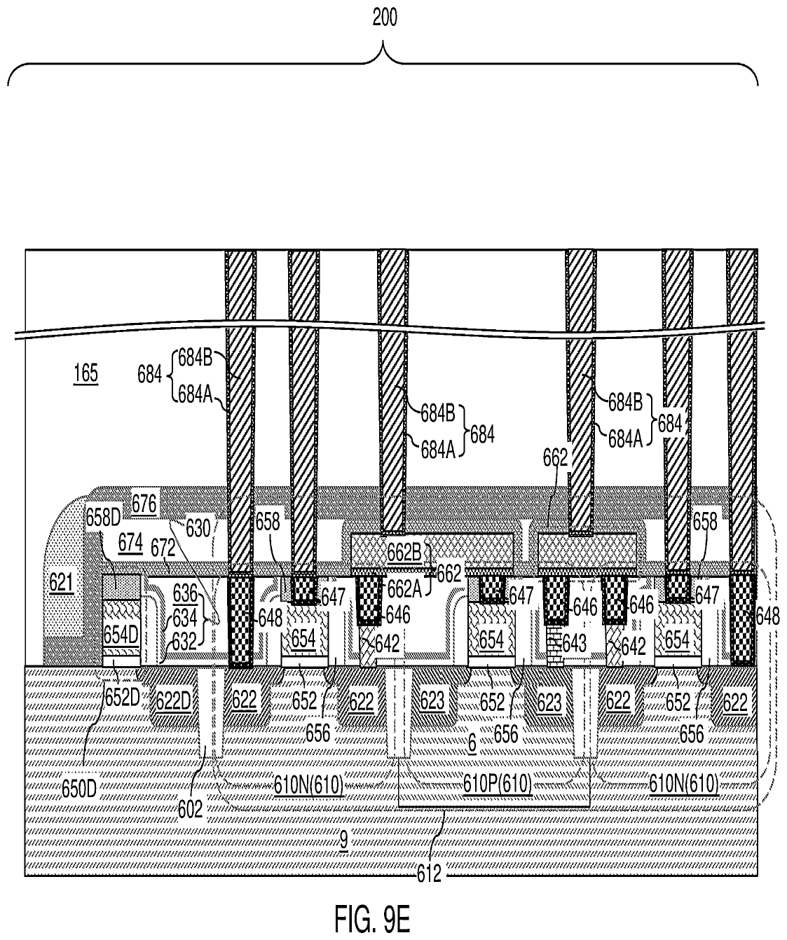

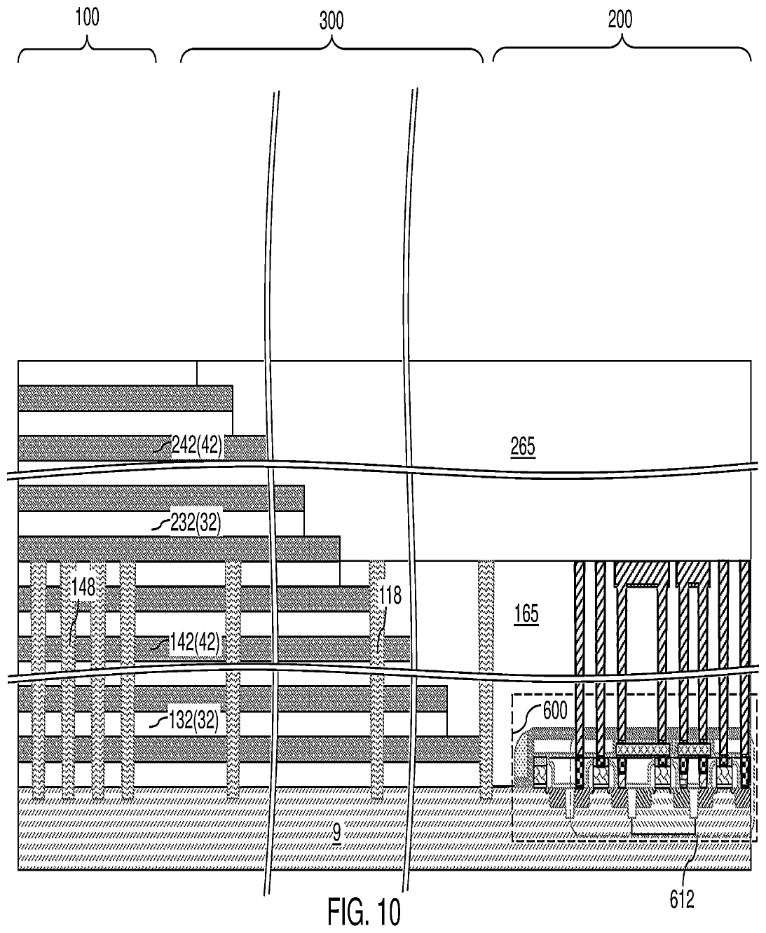

FIG. 9A is a vertical cross-sectional view of the exemplary structure after formation of first-tier metal interconnect structures (682, 684) according to an embodiment of the present disclosure. FIG. 9B is a top-down view of the exemplary structure of FIG. 9A. The zig-zag plane A-A′ corresponds to the cut plane of the vertical cross-sectional view of FIG. 9A. FIGS. 9C, 9D, and 9E are magnified views of a portion of a peripheral region 200 in the first, second, and third configuration, respectively, of the exemplary structure of the first, second and third embodiments, respectively, after the processing steps of FIGS. 9A and 9B.

Referring to FIGS. 9A-9E, via cavities or integrated line-and-via cavities can be formed in the first retro-stepped dielectric material portion 165, and through the capping-level dielectric layers (672, 674, 676) (in case the dielectric layers 672 and 674 are employed as illustrated in FIGS. 9C and 9E) or the passivation capping layer 676 (in case only the passivation capping layer 676 is employed as illustrated in FIG. 9D), and can be filled with at least one metallic material to form metallic structures (682, 684). The metallic structures (682, 684) may comprise first-tier integrated line-and-via structures 682 and first-tier metal via structures 684.

In the first configuration of the first embodiment illustrated in FIG. 9C, first-tier integrated line-and-via structures 682 and first-tier metal via structures 684 are formed in the first retro-stepped dielectric material portion 165 and through the capping-level dielectric layers (672, 674, 676). In the second configuration of the second embodiment illustrated in FIG. 9D, first-tier integrated line-and-via structures 682 and first-tier metal via structures 684 are formed in the first retro-stepped dielectric material portion 165 and through the passivation capping layer 676. In case the first configuration or the second configuration is employed, a photoresist layer (not shown), which is also referred to as line-level photoresist layer, can be applied over the first alternating stack (132, 142) and the first retro-stepped dielectric material portion 165, and can be lithographically patterned to form openings having the same pattern as the metallic line structures 662 as described with reference to FIG. 3A. An anisotropic etch process can be performed to transfer the pattern of the openings in the photoresist layer into an upper portion of the first retro-stepped dielectric material portion to form line cavities. The line cavities have the same pattern as the pattern of the metallic line structures 662 as described with reference to FIG. 3A. The depth of the line cavities may be in a range from 200 nm to 600 nm, although lesser and greater depths may also be employed. The photoresist layer can be subsequently removed, for example, by ashing.

The third configuration of the third embodiment illustrated in FIG. 9E can be derived from the first configuration of the exemplary structure by omitting the processing steps for forming the line cavities in the first retro-stepped dielectric material portion 165. Thus, application and patterning of the line-level photoresist layer may be omitted in the third configuration of the exemplary structure.

For each configuration of the exemplary structure, i.e., for the first, second, and third configurations of the exemplary structure as illustrated in FIGS. 9C, 9D, and 9E, a photoresist layer (not shown), which may also be referred to as a via-level photoresist layer, can be applied over the first alternating stack (132, 142) and the first retro-stepped dielectric material portion 165, and can be lithographically patterned to form openings therein. At this processing step, a first subset of the active regions (622, 623) is contacted by semiconductor pillar structures (642, 643), and a second subset of the active regions (622, 623) is not contacted by the semiconductor pillar structures (642, 643). Each semiconductor pillar structure (642, 643) is contacted by a respective one of the pedestal-contact via structures 646. Each active region (622, 623) that is not contacted by any semiconductor pillar structure (642, 643) is contacted by a respective one of the active-region-contact via structures 648. Each gate electrodes 654 is contacted by a respective one of the gate-contact via structures 647.

In the first configuration illustrated in FIG. 9C and in the second configuration illustrated in FIG. 9D, additional openings are formed in the photoresist layer over the areas of the first subset of the active regions (622, 623) (which overlap with the areas of the semiconductor pillar structures (642, 643)), and over the areas of the first subset of the active regions (622, 623) (which overlap with the areas of the semiconductor pillar structures (642, 643)). In the first configuration illustrated in FIG. 9C, the pattern of the additional openings may include the pattern of the semiconductor pillar structures (642, 643) and the pattern of the active-region-contact via structures 648. In the second configuration illustrated in FIG. 9D, the pattern of the additional openings in the photoresist layer may be formed within the areas of the semiconductor pillar structures (642, 643) and within the areas of the first subset of the active regions (622, 623).

In the third configuration illustrated in FIG. 9E, the pattern of the additional opening can be changed such that the additional openings in the photoresist layer are formed within the areas of the metallic line structures 662. In the third configuration illustrated in FIG. 9E, the pattern of the additional openings may not correspond to the pattern of the first subset of the active regions (622, 623) and the first subset of the active regions (622, 623). Instead, the additional openings in the photoresist layer may be formed within the areas of the metallic line structures 662.

An anisotropic etch process may be performed to transfer the pattern of the openings in the photoresist layer (i.e., the via-level photoresist layer) through the first retro-stepped dielectric material portion 165, and through the capping-level dielectric layers (672, 674, 676) (in case the capping-level dielectric layers (672, 674, 676) are employed as illustrated in FIGS. 9C and 9E) or the passivation capping layer 676 (in case the passivation capping layer 676 is employed as illustrated in FIG. 9D). Via cavities are formed over the areas of the metallic contact via structures (647, 648, 646).

In the first configuration illustrated in FIG. 9C, integrated line-and-via cavities are formed such that top surfaces of metallic line structures 662 are exposed underneath the integrated line-and-via cavities. In one embodiment, at least two top surface segments of a metallic line structure 662 may be exposed underneath an integrated line-and-via cavity.

In the second configuration illustrated in FIG. 9D, integrated line-and-via cavities are formed such that top surfaces of at least two metallic contact via structures (647, 648, 646) are exposed underneath an integrated line-and-via cavity.

In the third configuration illustrated in FIG. 9E, via cavities can be formed such that top surfaces of metallic line structures 662 are exposed underneath the via cavities. In one embodiment, a top surface segments of a metallic line structure 662 may be exposed underneath a via cavity.

An optional metallic barrier liner layer and a metallic fill material layer can be subsequently deposited in each via cavity and in each line-and-via cavity (in the case of the first configuration or the second configuration). The metallic barrier liner layer comprises a metallic nitride material that is thermally stable in an elevated temperature range such as a temperature range from 800 degrees Celsius to 1,050 degrees Celsius. For example, the metallic barrier line layer may comprise and/or may consist essentially of WN, MoN, TiN, or TaN. The thickness of the metallic barrier liner layer may be in a range from 5 nm to 50 nm, although lesser and grater thicknesses may also be employed.

The metallic fill material layer comprises a metal that is thermally stable in the elevated temperature range of the subsequent anneal process to be employed during formation of a three-dimensional memory array. In one embodiment, the metallic fill material layer comprises, and/or consists essentially of, a refractory metal having a melting temperature higher than 2,200 degrees Celsius, such as W, Mo, or Ta

Excess portions of the metallic barrier liner layer and the metallic fill material layer can be removed from above the horizontal plane including the top surface of the first retro-stepped dielectric material portion 165 by performing a planarization process, such as a chemical mechanical polishing process. Each remaining portion of the combination of the metallic barrier liner layer and the metallic fill material layer that fills an integrated line-and-via cavity constitutes a first-tier integrated line-and-via structure 682. Each remaining portion of the combination of the metallic barrier liner layer and the metallic fill material layer that fills a via cavity constitutes a first-tier via structure 684. Each first-tier integrated line-and-via structure 682 comprises a metallic barrier liner 682A which is a patterned remaining portion of the metallic barrier liner layer, and a metallic fill material portion 682B which is a remaining portion of the metallic fill material layer. Each first-tier via structure 684 comprises a metallic barrier liner 684A which is a patterned remaining portion of the metallic barrier liner layer, and a metallic fill material portion 684B which is a remaining portion of the metallic fill material layer.

The first-tier integrated line-and-via structures 682 in the first configuration may be employed as additional local interconnect structures that provide a parallel electrical connection to a respective local interconnect structure (642, 643, 646, 647, 662). In other words, the local interconnect structures (642, 643, 646, 647, 662, 682) in the first configuration comprise the first-tier integrated line-and-via structures 682 in addition to local interconnect structures (642, 643, 646, 662) that are formed underneath the first retro-stepped dielectric material portion 165.

The first-tier integrated line-and-via structure 682 in the second configuration function as components of local interconnect structures (642, 643, 646, 647, 682). Specifically, a contiguous combination of an optional first semiconductor pillar structure (642 or 643), an optional second semiconductor pillar structure (642 or 643), and at least two metallic contact via structures (647, 646), and a first-tier integrated line-and-via structure 682 constitutes a local interconnect structure (642, 643, 646, 647, 682).

In the first configuration and in the second configuration, metallic structures (such as the first-tier integrated line-and-via structures 682) can be formed in a dielectric material portion (such as a first retro-stepped dielectric material portion 165) and through a dielectric passivation layer (such as a passivation capping layer 676). In the second configuration illustrated in FIG. 9D, each of the metallic structures (such as a first-tier integrated line-and-via structure 682) comprises a first metal via portion contacting the top surface of a metallic contact via structure (647, 648, 646) and a second metal via portion contacting a top surface of a second metallic contact via structures (647, 648, 646). In one embodiment, at least one of the first-tier integrated line-and-via structures 682 may comprise a respective metal line portion having a top surface located within a horizontal plane including a top surface of the retro-stepped dielectric material portion (such as a first retro-stepped dielectric material portion 165) and connected to and overlying the first metal via portion and the second metal via portion.

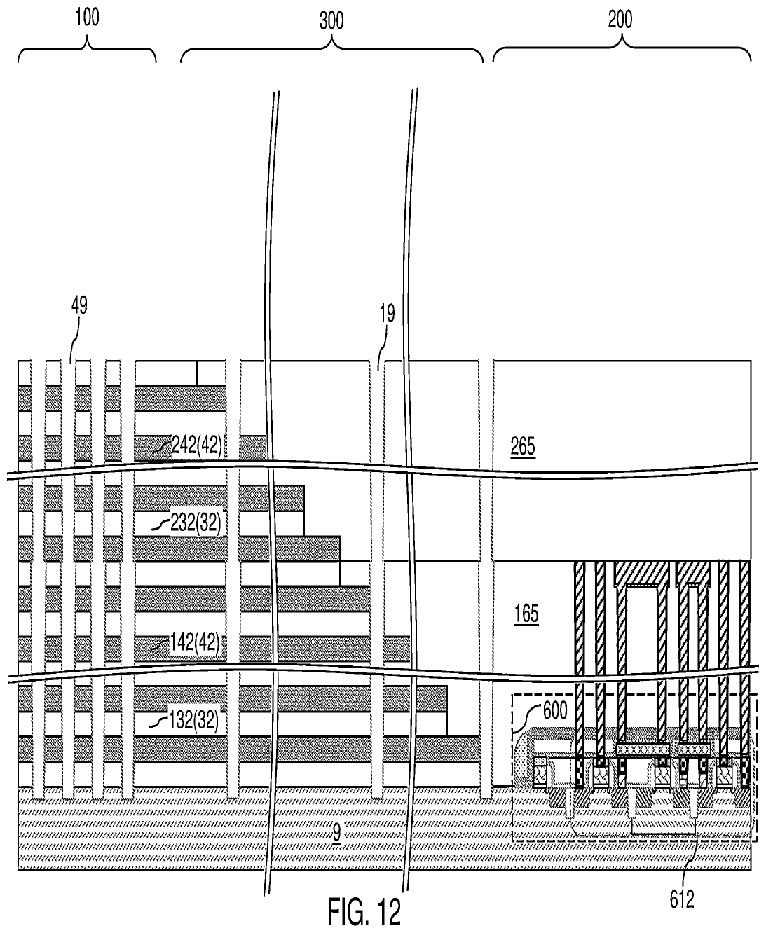

Referring to FIG. 12, a second alternating stack of second insulating layers 232 and second spacer material layers can be formed over the first-tier alternating stack (132, 142). In one embodiment, the second spacer material layers may comprise second sacrificial material layers 242. In this case, a second alternating stack (232, 242) of second insulating layers 232 and second sacrificial material layers 242 can be formed over the first-tier alternating stack (132, 142). The second insulating layers 232 are a second subset of the insulating layers 32 that are formed to provide the three-dimensional memory device of the present disclosure, and the second sacrificial material layers 242 are a second subset of the sacrificial material layers 42 that are formed to provide the three-dimensional memory device of the present disclosure. In one embodiment, the second insulating layers 232 may comprise silicon oxide layers, and the second sacrificial material layers 242 may comprise silicon nitride layers.

The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 1,024, such as from 32 to 256, although lesser and greater number of repetitions may also be employed. Each of the second insulating layers 232 may have the same material composition and the same thickness as the first insulating layers 132. Each of the second sacrificial material layers 242 may have the material composition and the same thickness as the first sacrificial material layers 142.

The second alternating stack (232, 242) are patterned such that the second alternating stack (232, 242) is removed from the peripheral region 200, is not removed from the memory array region 100, and is partially removed from the contact region 300 such that second stepped surfaces of the second alternating stack (232, 242) are formed in the contact region 300. The second stepped surfaces may be laterally offset toward the memory array region 100 relative to the first stepped surfaces. The second stepped cavity can have various first stepped surfaces such that the horizontal cross-sectional shape of the second stepped cavity changes in steps as a function of the vertical distance from the top surface of the substrate 9. Each second sacrificial material layer 242 other than a topmost second sacrificial material layer 242 within the second alternating stack (232, 242) laterally extends farther than any overlying second sacrificial material layer 242 within the second alternating stack (232, 242) in the terrace region. The second stepped surfaces of the second alternating stack (232, 242) continuously extend from a bottommost layer within the second alternating stack (232, 242) to the topmost layer within the second alternating stack (232, 242).

A second retro-stepped dielectric material portion 265 (i.e., an insulating fill material portion) can be formed in the second stepped cavity by deposition of a dielectric material therein. For example, a dielectric material such as silicon oxide can be deposited in the second stepped cavity. Excess portions of the deposited dielectric material can be removed from above the top surface of the topmost second insulating layer 232, for example, by chemical mechanical planarization (CMP). The remaining portion of the deposited dielectric material filling the second stepped cavity constitutes the second retro-stepped dielectric material portion 265. If silicon oxide is employed for the second retro-stepped dielectric material portion 265, the silicon oxide of the second retro-stepped dielectric material portion 265 may optionally be doped with dopants such as B, P, and/or F. In one embodiment, the second retro-stepped dielectric material portion 265 overlies and contacts the second stepped surfaces, and has a top surface that is coplanar with the top surface of the topmost second insulating layer 232. The top surface of the second retro-stepped dielectric material portion 265 may be formed within the horizontal plane including the topmost layer of the second alternating stack (232, 242) such as a topmost second insulating layer 232.

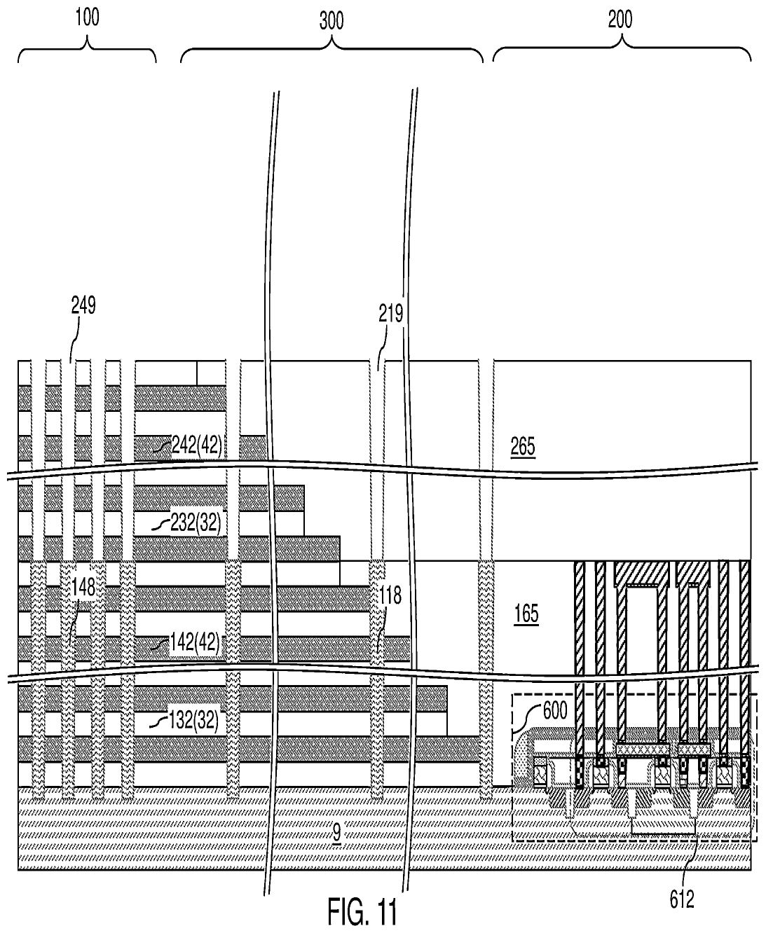

Referring to FIG. 11, a photoresist layer (not shown) can be applied over the second alternating stack (232, 242) and the second retro-stepped dielectric material portion 265, and can be lithographically patterned to form openings therein. The pattern of the openings in the photoresist layer may be the same as the pattern of the first-tier memory openings 149 and the first-tier support openings 119, which is described with reference to FIGS. 7A and 7B. An anisotropic etch process can be performed to transfer the pattern of the openings in the photoresist layer through the second alternating stack (232, 242) and the portion of the second retro-stepped dielectric material portion 265 located in the contact region 300. Second-tier memory openings 249 are formed over the first-tier sacrificial memory opening fill structures 148, and second-tier support openings 219 are formed over the first-tier sacrificial support opening fill structures 118. The photoresist layer can be subsequently removed, for example, by ashing.

Referring to FIG. 12 the sacrificial fill material of the first-tier sacrificial memory opening fill structures 148 and the first-tier sacrificial support opening fill structures 118 can be removed selective to the materials of the second alternating stack (232, 242), the first alternating stack (132, 142), the retro-stepped dielectric material portions (165, 265), and the substrate 9. A memory openings 49, which is also referred to as an inter-tier memory opening 49, can be formed in each volume that includes the volume of a second-tier memory opening 249 and the volume of a first-tier memory opening 149. A support openings 19, which is also referred to as an inter-tier support opening 19, can be formed in each volume that includes the volume of a second-tier support opening 219 and the volume of a first-tier support opening 119.

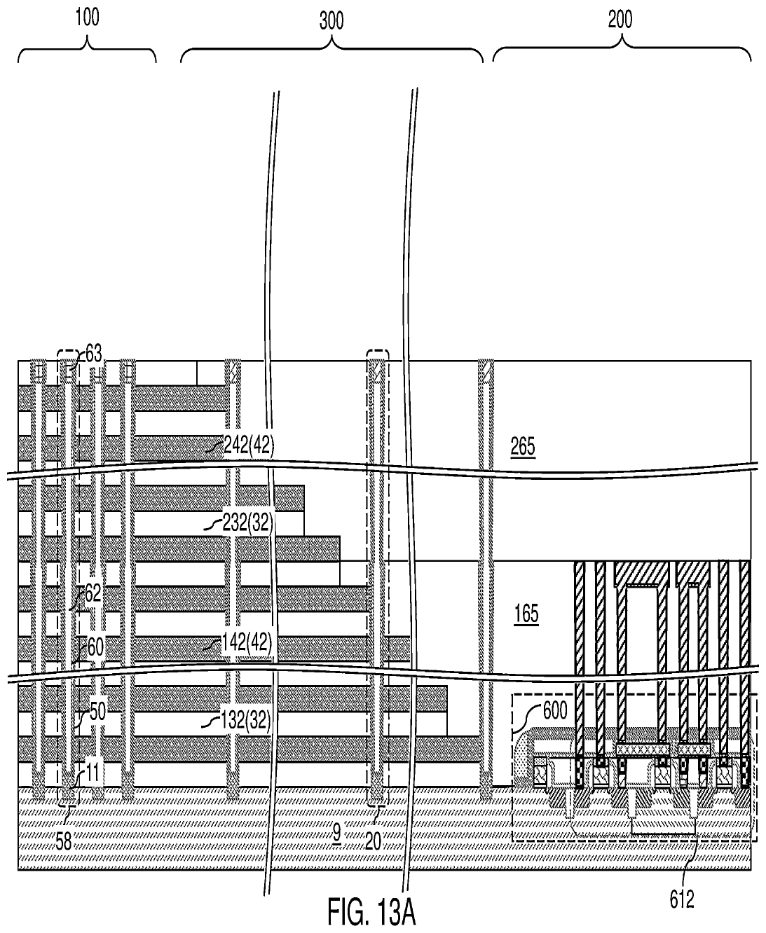

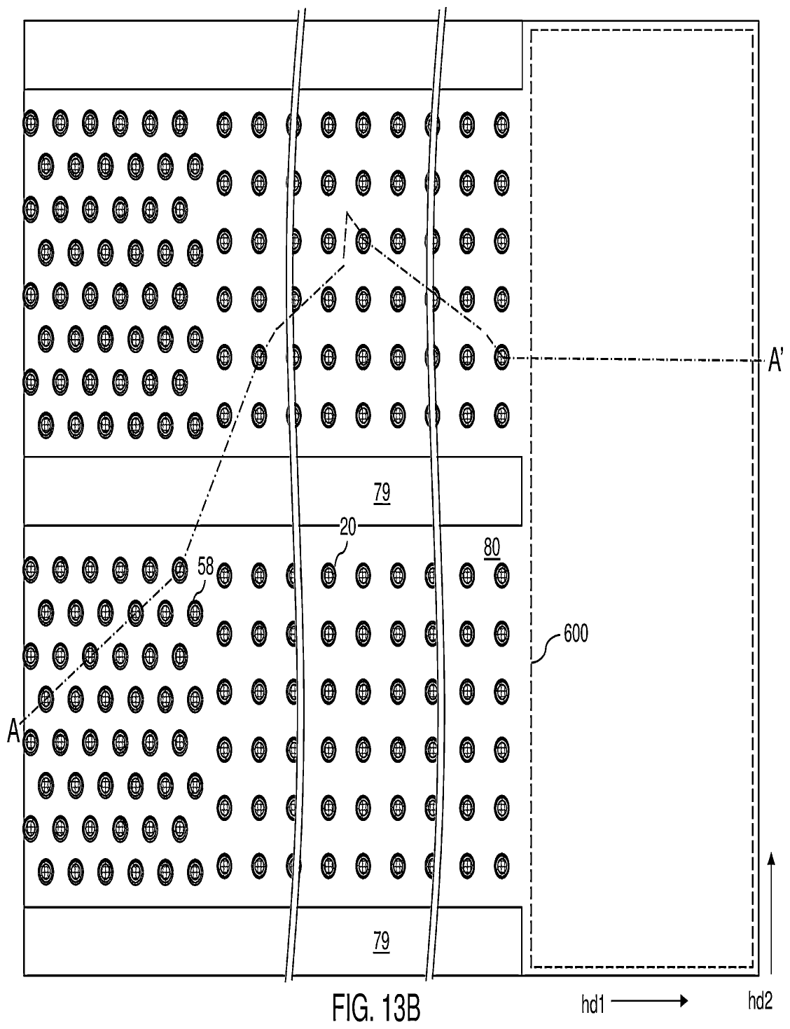

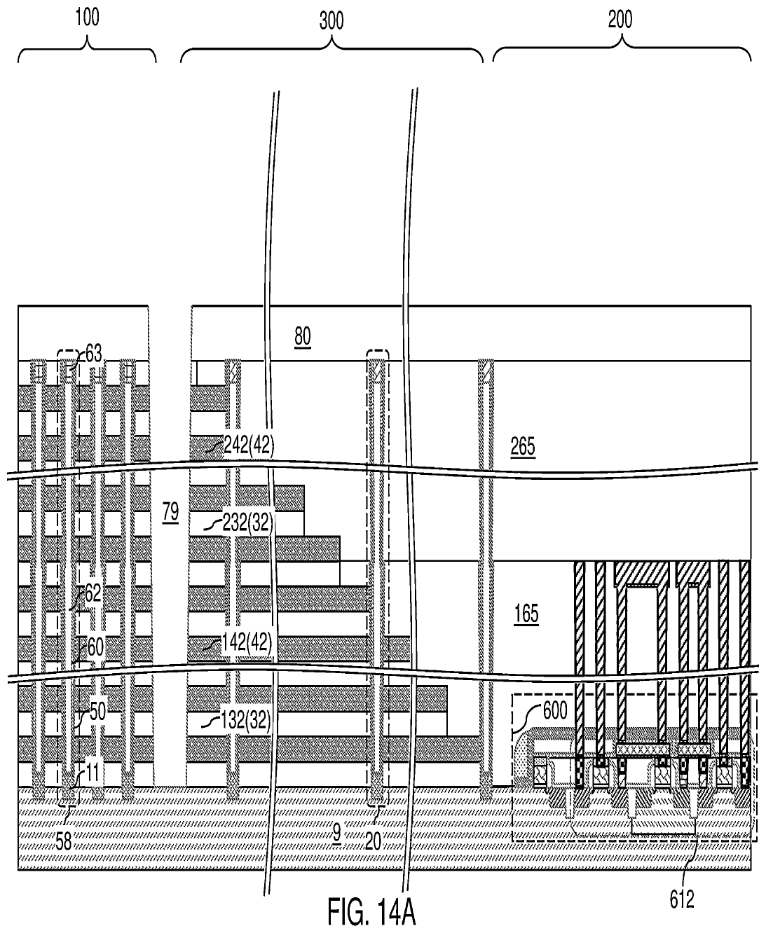

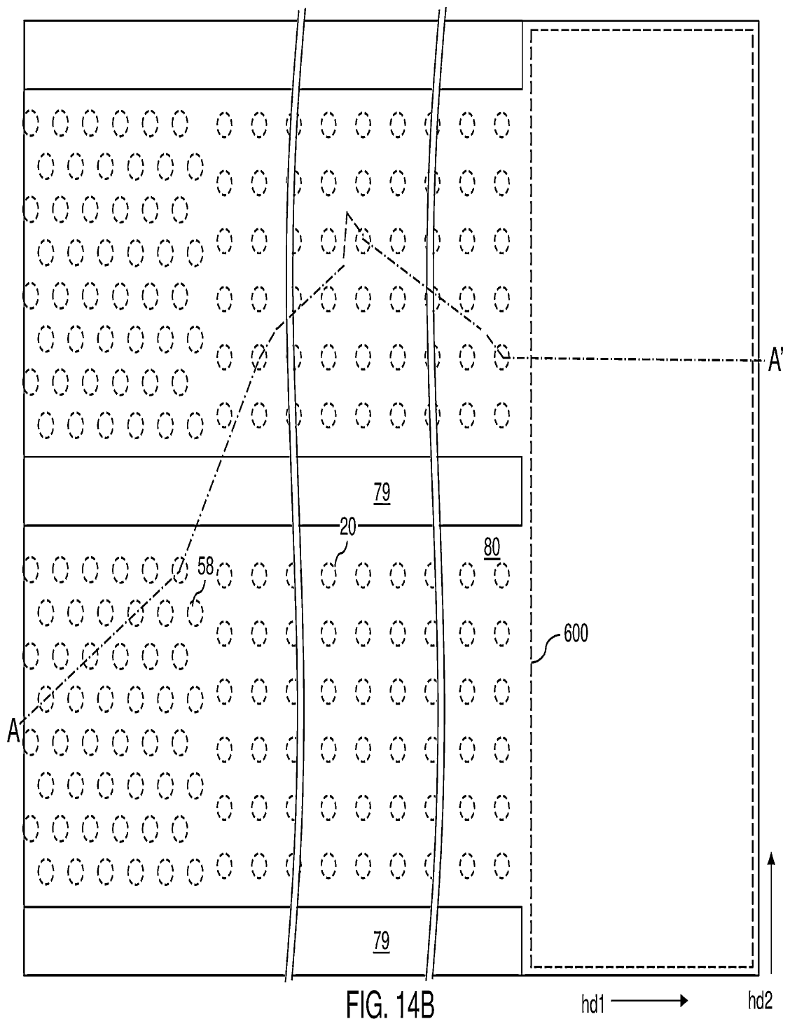

Referring to FIGS. 13A and 13B, a sequence of processing steps can be performed to form a memory opening fill structure 58 in each memory opening 49, and to form a support pillar structure 20 in each support opening 19. For example, each of the memory opening fill structures 58 and the support pillar structures 20 may comprise a pedestal channel portion 11 that can be grown from physically exposed surfaces of the substrate 9 by a selective semiconductor material deposition process, a memory film 50 that includes at least a memory material layer such as a charge storage layer, a vertical semiconductor channel 60, a dielectric core 62, and a drain region 63. In one embodiment, the memory film 50 may be formed by sequentially conformally depositing a blocking dielectric layer, a memory material layer (such as a charge storage layer), and an optional dielectric liner (which may comprise a tunneling dielectric layer if the charge storage layer is employed as the memory material layer). An anisotropic etch process may be performed to remove horizontally-extending portions of the memory film prior to formation of the vertical semiconductor channel 60 in each of the memory openings 49 and the support openings 19 to induce direct contact between each vertical semiconductor channel 60 and a respective underlying pedestal channel portion 11. A dielectric core 62 may be formed to fill a remaining void within each of the memory openings 49 and the support openings 19. A doped semiconductor material portion can be deposited in the top portion of each of the memory openings 49 and the support openings 19 to form a drain region 63.

The set of all material portions that fills a memory opening 49 constitutes a memory opening fill structure 58. The set of all material portions that fills a support opening 19 constitutes a support pillar structure 20, which is an electrically inactive structure that does not have any electrically active node and provides structural support to a three-dimensional memory device. Each contiguous combination of a memory film 50 and a vertical semiconductor channel 60 in a memory opening 49 constitutes a memory stack structure (50, 60) configurated to store memory bits therein. Each portion of the memory material layer located at levels of the sacrificial material layers 42 constitutes a memory element. Thus, each memory opening fill structure 58 comprises a vertical stack of memory elements.

Referring to FIGS. 14A and 14B, a dielectric material, such as undoped silicate glass or a doped silicate glass, can be deposited over second alternating stack (232, 242) and the second retro-stepped dielectric material portion 265 to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stacks {(132, 142), (232, 242)}, and the retro-stepped dielectric material portions (265, 165). Lateral isolation trenches 79 laterally extending along the first horizontal direction hd1 (which may be a word line direction) can be formed through the contact-level dielectric layer 80, the alternating stacks {(132, 142), (232, 242), and the retro-stepped dielectric material portions (265, 165). Each of the lateral isolation trenches 79 may comprise a respective pair of lengthwise sidewalls that are parallel to the first horizontal direction hd1 and vertically extend from the substrate 9 to the top surface of the contact-level dielectric layer 80. A top surface of the substrate 9 can be physically exposed underneath each lateral isolation trench 79. The photoresist layer can be subsequently removed, for example, by ashing.

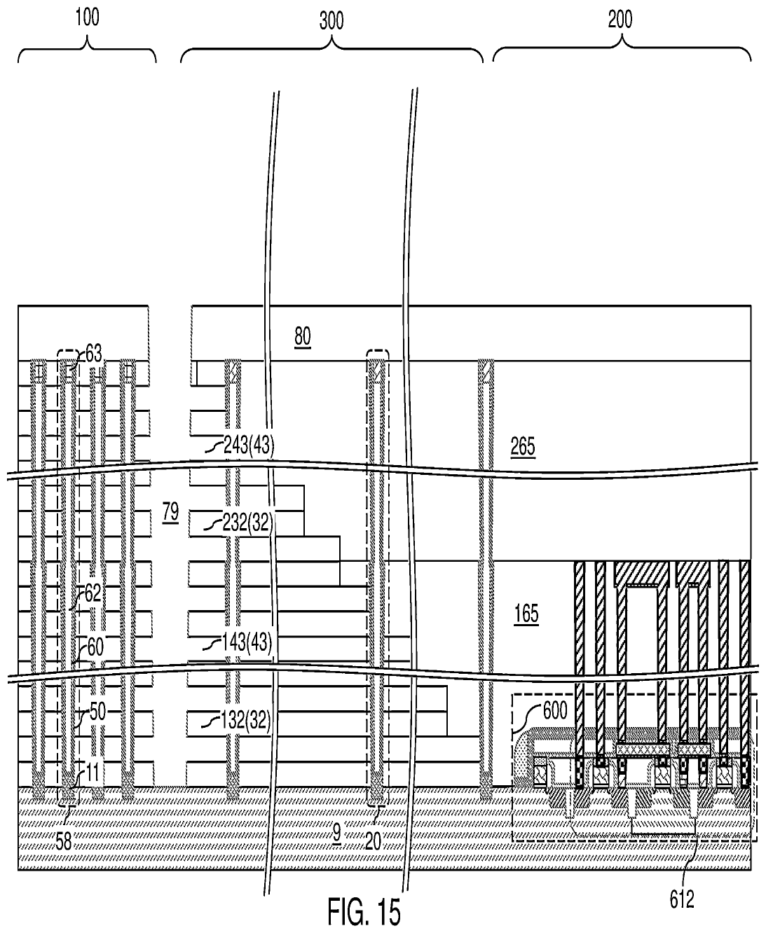

Referring to FIG. 15, an isotropic etch process can be performed to remove the sacrificial material layers 42 selective to the insulating layers 32, the memory opening fill structures 58, the retro-stepped dielectric material portions (165, 265), and the substrate 9. In an illustrative example, the insulating layers 32 may comprise silicon oxide, the sacrificial material layers 42 may comprise silicon nitride. In this case, the isotropic etch process that removes the sacrificial material layers 42 may comprise a wet etch process employing hot phosphoric acid. Laterally-extending cavities 43 can be formed in volumes from which the sacrificial material layers (142, 242, 342) are removed. The laterally-extending cavities 43 may comprise first-tier laterally-extending cavities 143 that are formed in volumes from which first sacrificial material layers 142 are removed and second-tier laterally-extending cavities 243 that are formed in volumes from which second sacrificial material layers 242 are removed. Sidewall surface segments of the memory opening fill structures 58 can be physically exposed to the laterally-extending cavities 43.

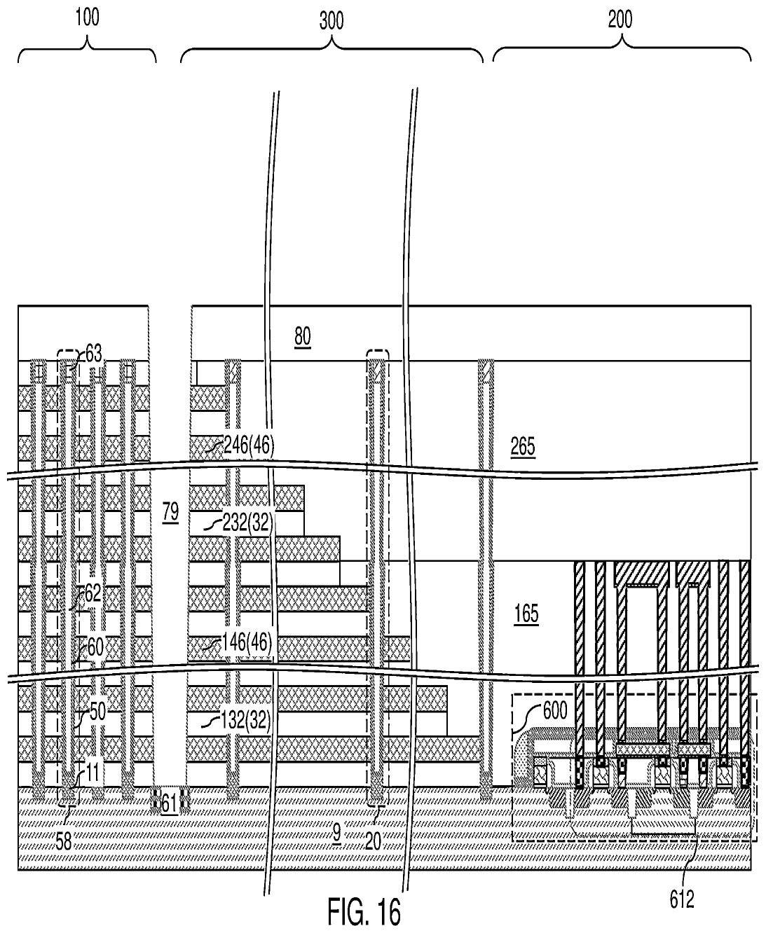

Referring to FIG. 16, source regions 61 can be formed underneath the lateral isolation trenches 79 by implanting electrical dopants into a surface portion of the substrate 9. An outer blocking dielectric layer (not shown), such as an aluminum oxide layer, can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. Specifically, the electrically conductive layer 46 may comprise first electrically conductive layers 146 that are formed in the first-tier laterally-extending cavities 143, and second electrically conductive layers 246 that are formed in the second-tier laterally-extending cavities 243. An alternating stack of insulating layers 32 and electrically conductive layers 46 can be formed between each neighboring pair of lateral isolation trenches 79 over the substrate 9. A plurality of alternating stacks of insulating layers 32 and electrically conductive layers 46 can be laterally spaced apart among one another by the lateral isolation trenches 79.

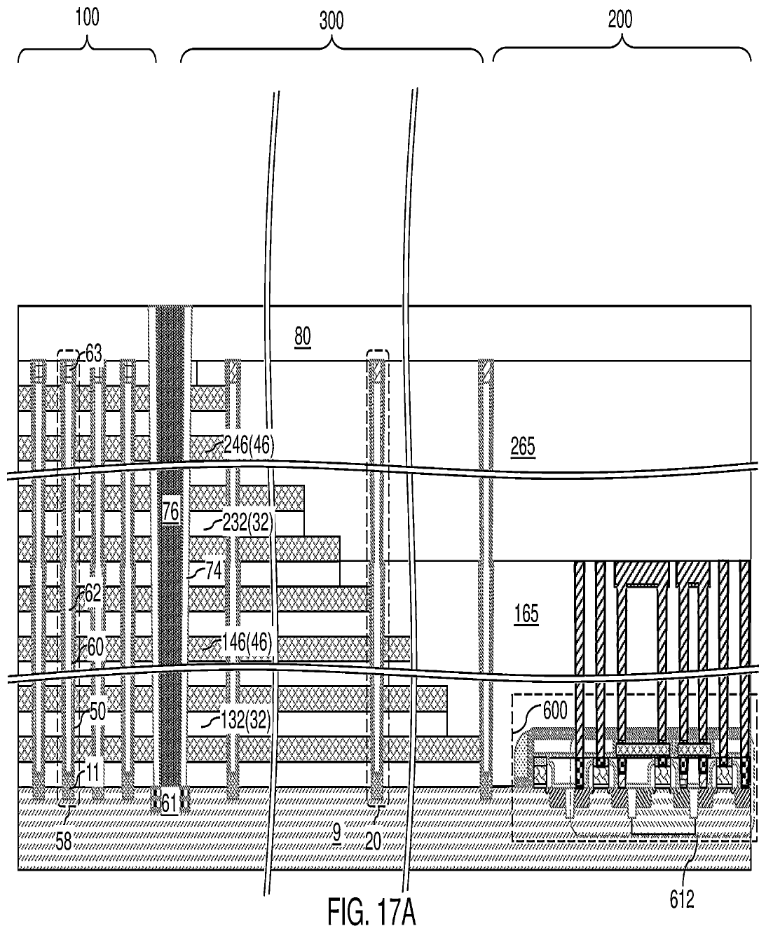

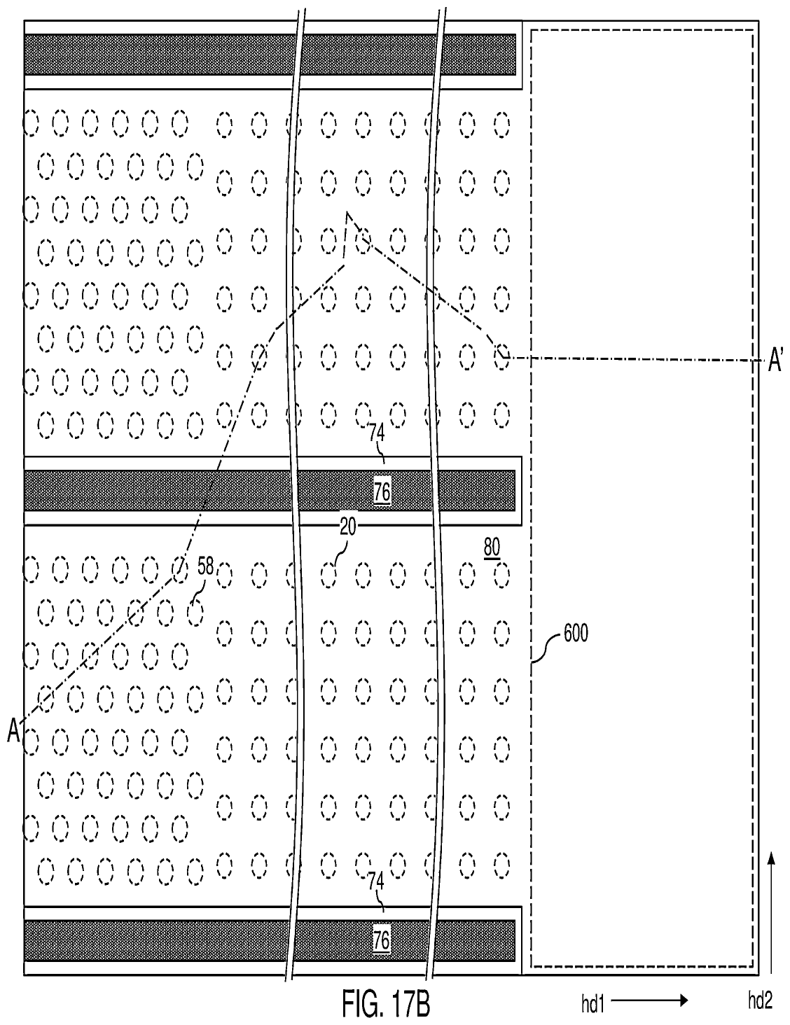

Referring to FIGS. 17A and 17B, an insulating spacer material layer can be conformally deposited in the lateral isolation trenches 79 and over the contact-level dielectric layer 80. An anisotropic etch process may be performed to remove horizontally-extending portions of the insulating spacer material layer. Each remaining laterally-elongated tubular portion of the insulating spacer material layer in peripheral regions of the lateral isolation trenches 79 constitute an insulating spacer 74. At least one conductive fill material (such as at least one metallic fill material) may be conformally deposited in remaining volumes of the lateral isolation trenches 79. Excess portions of the at least one conductive fill material may be removed from above the contact-level dielectric layer 80, for example, by a planarization process, which may employ a recess etch process and/or a chemical mechanical polishing process. Each remaining portion of the at least one conductive fill material that fills a respective lateral isolation trench 79 constitutes a conductive wall structure 76. Each contiguous combination of an insulating spacer 74 and a conductive wall structure 76 constitutes an isolation trench fill structure (74, 76) that fills a respective lateral isolation trench 79.

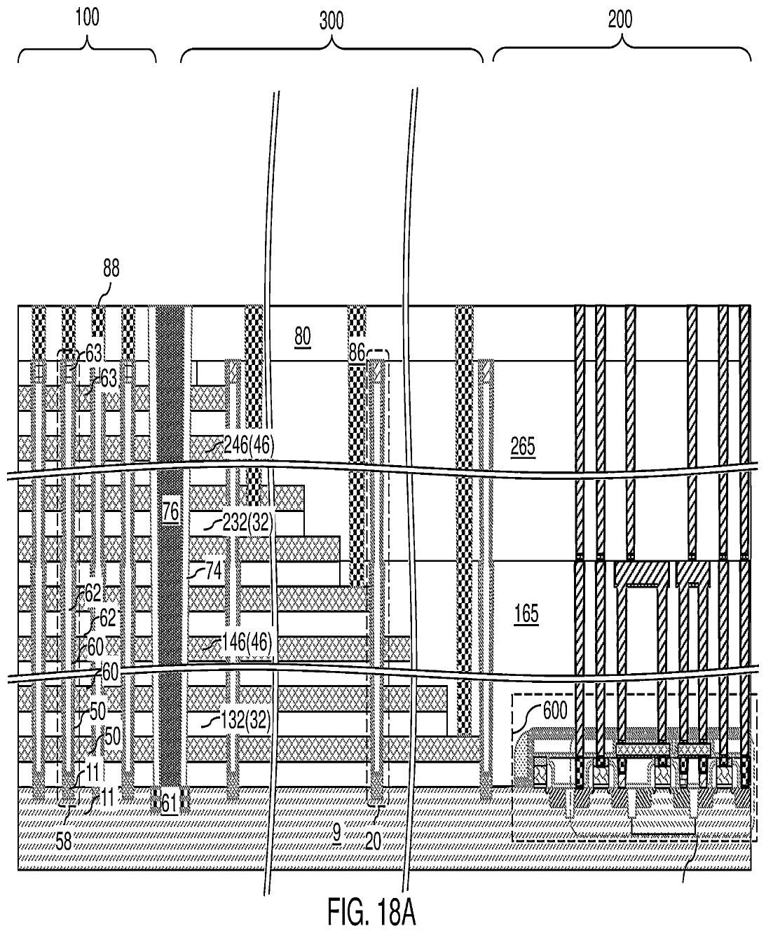

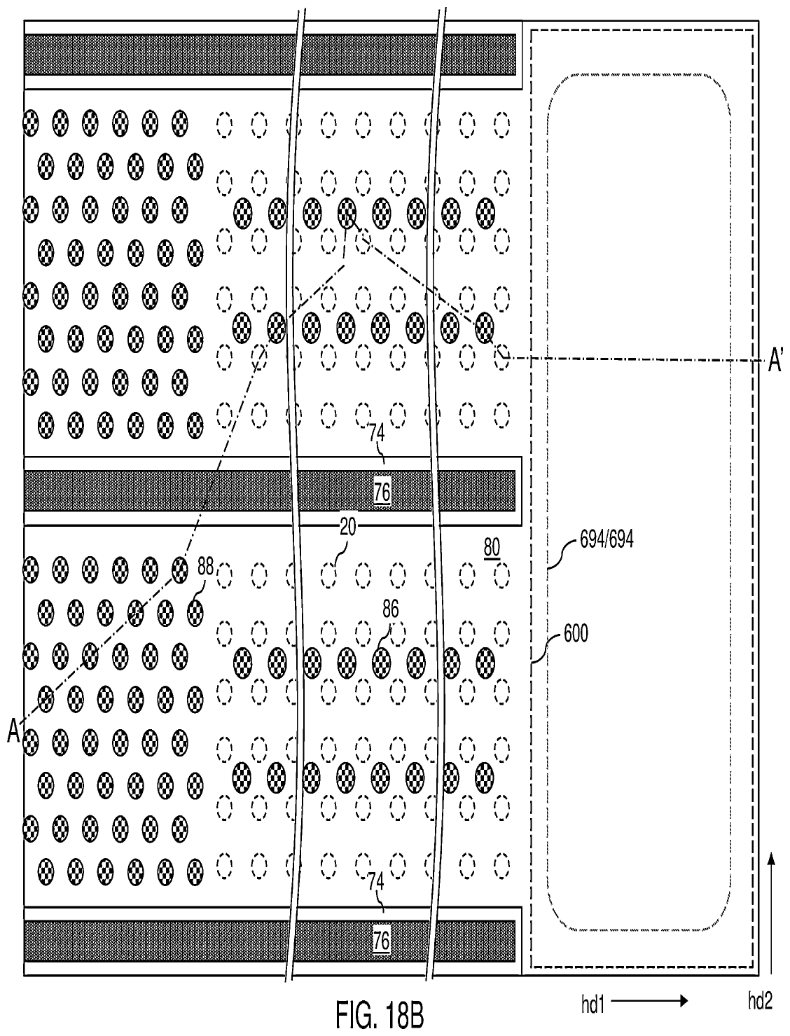

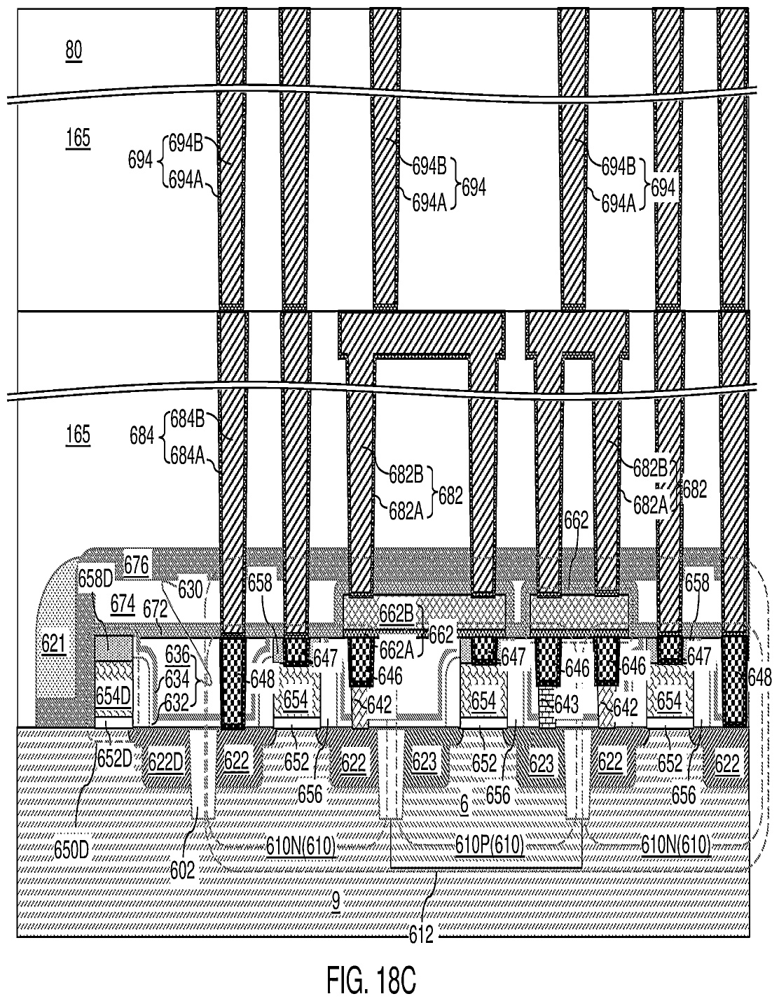

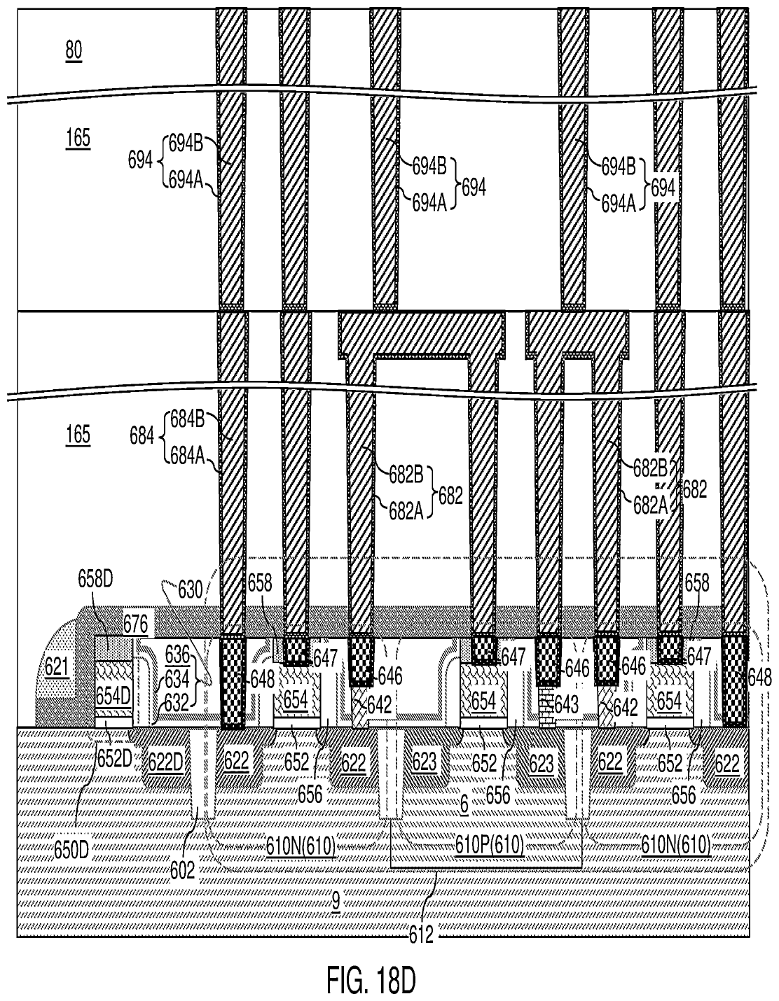

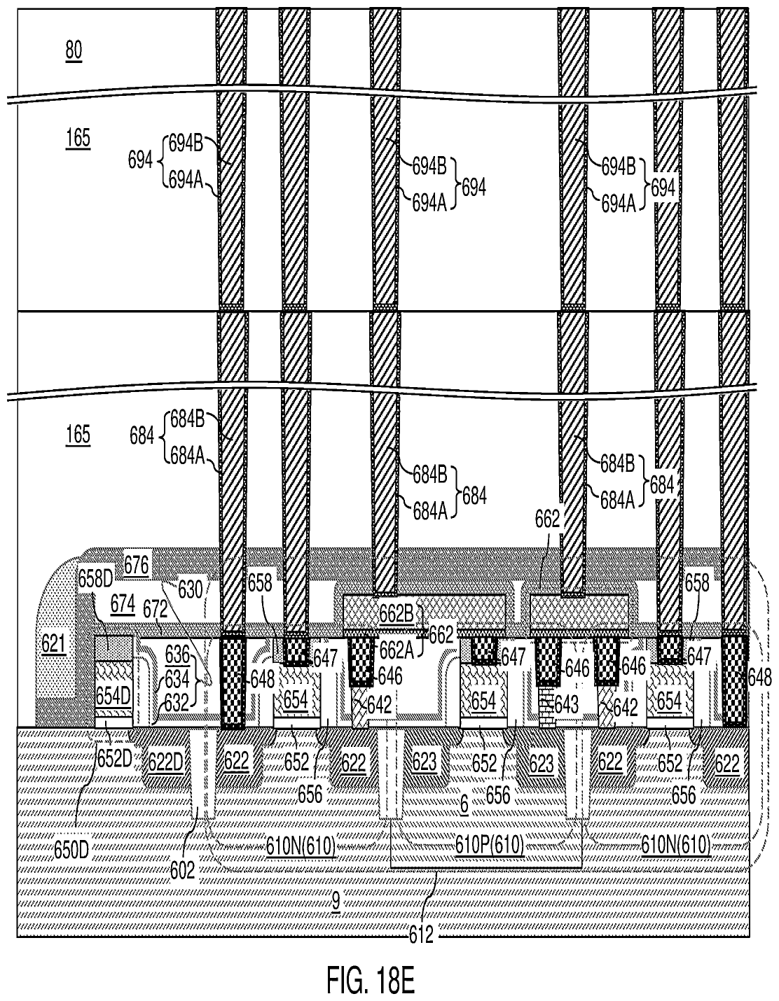

FIG. 18A is a vertical cross-sectional view of the exemplary structure after formation of various contact via structures (86, 88) and second-tier metal interconnect structures according to an embodiment of the present disclosure. FIG. 18B is a top-down view of the exemplary structure of FIG. 18A. The zig-zag plane A-A′ corresponds to the cut plane of the vertical cross-sectional view of FIG. 18A. FIGS. 18C, 18D, and 18E are magnified views of a portion of a peripheral region 200 in the first, second, and third configuration, respectively, of the exemplary structure of the first, second and third embodiment, respectively, after the processing steps of FIGS. 18A and 18B.

Referring to FIGS. 18A-18E, a first photoresist layer (not shown) can be applied over the contact-level dielectric layer 80, and can be lithographically patterned to form openings over the areas of the memory opening fill structures 58. A first anisotropic etch process can be performed to form drain contact via cavities through the contact-level dielectric layer 80. The first anisotropic etch process may be selective to the semiconductor material of the drain regions 63. A top surface of a drain region 63 may be physically exposed underneath each drain contact via cavity. The first photoresist layer can be subsequently removed, for example, by ashing.

A second photoresist layer (not shown) can be applied over the contact-level dielectric layer 80, and can be lithographically patterned to form first openings over the first stepped surfaces of the first alternating stack (132, 146) and the second stepped surfaces of the second alternating stack (232, 246), and to form second openings over the first-tier metal interconnect structures (682, 684). An anisotropic etch process can be performed to transfer the pattern of the openings in the second photoresist layer through the second retro-stepped dielectric material portion 265 and optionally through the first retro-stepped dielectric material portion 165. A layer contact via cavity can be formed underneath each first opening in the first photoresist layer. A top surface segment of an electrically conductive layer 46 can be physically exposed underneath each layer contact via cavity. A connection via cavity vertically extending through the entire thickness of the second retro-stepped dielectric material portion 265 can be formed underneath each second opening in the second photoresist layer. A top surface of a first-tier metal interconnect structure (682, 684) can be physically exposed underneath each connection via cavity. The second photoresist layer can be subsequently removed, for example, by ashing.

At least one metallic material layer, such as a combination of a metallic barrier liner layer and a metallic fill material layer, can be deposited in the drain contact via cavities, layer contact via cavities, and the connection via cavities. The metallic barrier liner layer may comprise any metallic barrier material such as TiN, TaN, WN, MoN, TiC, TaC, WC, etc. The metallic fill material may comprise any metallic fill material such as W, Mo, Co, Ru, Ti, Ta, Cu, etc. Excess portions of the at least one metallic material layer can be removed from above the horizontal plane including the top surface of the contact-level dielectric layer 80 by a planarization process such as a chemical mechanical polishing process.

Each remaining portion of the at least one metallic material layer filling a respective drain contact via cavity constitutes a drain contact via structure 88. Each drain contact via structure 88 can contact the top surface of a respective underlying drain region 63. Each remaining portion of the at least one metallic material layer filling a respective layer contact via cavity constitutes a layer contact via structure 86. Each layer contact via structure 86 contacts a top surface of a respective underlying electrically conductive layer 46. Each remaining portion of the at least one metallic material layer filling a respective connection via cavity constitutes a second-tier metal interconnect structure, which may comprise a second-tier via structure 694. Each second-tier via structure 694 comprises a metallic barrier liner 694A which is a patterned remaining portion of the metallic barrier liner layer, and a metallic fill material portion 694B which is a remaining portion of the metallic fill material layer.

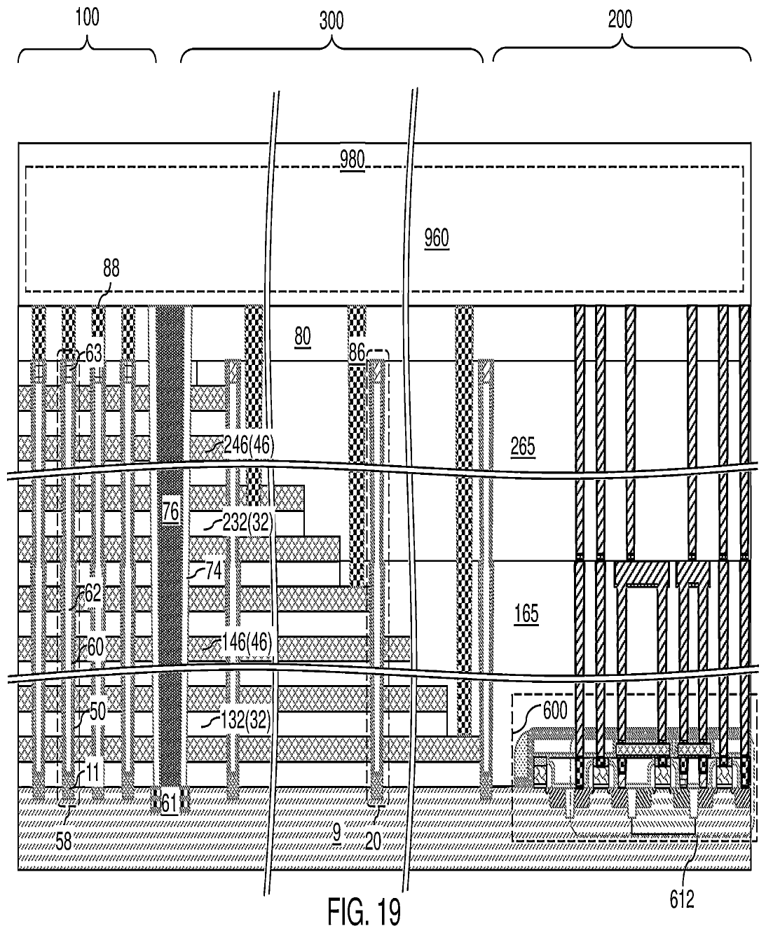

Referring to FIG. 19, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Referring to all drawings and according to various embodiments of the present disclosure, a device structure comprises a first field effect transistor 610, a second field effect transistor 610, and a local interconnect structure (642, 643, 646, 647, 662 and/or 682). The local interconnect structure includes a first semiconductor pillar structure (642 or 643) contacting a top surface of an active region (622 or 623) of the first field effect transistor, a first metallic contact via structure 646 contacting a top surface of the first semiconductor pillar structure (642 or 643), a metallic structure (662 or 682) contacting a top surface of the first metallic contact via structure 646, and a second metallic contact via structures (648 or 647) contacting a bottom surface of the metallic structure (662 or 682) and electrically connected to an electrical node of the second field effect transistor 610.

In one embodiment, the first field effect transistor 610 comprises a stack of a first gate dielectric 652, a first gate electrode 654, and a first gate cap dielectric 658; and a top surface of the first metallic contact via structures 646 and a top surface of the second metallic contact via structures (648 or 647) are located within a horizontal plane including a top surface of the first gate cap dielectric 658.

In one embodiment, the device structure comprises a gate-level dielectric layer 630 laterally surrounding gate electrodes 654 of the field effect transistors 610, wherein a top surface of the first metallic contact via structures 646 and a top surface of the second metallic contact via structures (648 or 647) are located within a horizontal plane including a topmost surface of the gate-level dielectric layer 630. In one embodiment, the first field effect transistor 610 comprises a first gate electrode 654 and a first gate cap dielectric 658 that overlies the first gate electrode 654; and a top surface of the first gate cap dielectric 658 is located within the horizontal plane. In one embodiment, the first semiconductor pillar structure (642 or 643) consists essentially of a first doped semiconductor material; and the second semiconductor pillar structure (642, 643) consists essentially of a second doped semiconductor material having a same semiconductor material composition as the first semiconductor pillar structure (642 or 643).

In one embodiment, the first semiconductor pillar structure (642 or 643) consists of a first single-crystalline semiconductor material that is in epitaxial alignment with a single-crystalline material in the active region (622, 623) of the first field effect transistor 610. In one embodiment, the electrical node (622, 623, or 654) of the second field effect transistor 610 comprises an active region (622, 623) of the second field effect transistor 610; and a second semiconductor pillar structure (642, 643) consists of a second single-crystalline semiconductor material that is in epitaxial alignment with a single-crystalline material in the active region (622, 623) of the second field effect transistor 610. In one embodiment, the first single-crystalline semiconductor material has a doping of a first conductivity type; and the second single-crystalline semiconductor material portion has a doping of a second conductivity type that is an opposite of the first conductivity type. In one embodiment, the electrical node (622, 623, or 654) of the second field effect transistor 610 comprises a gate electrode 654 of the second field effect transistor 610.

In one embodiment, the metallic structure (662 or 682) is in direct contact with a top surface of the second metallic contact via structures (646 or 647). In one embodiment, the metallic structure (662 or 682) comprises a metallic line structure which comprises: a metallic barrier liner 662A in contact with the top surface of the first metallic contact via structures 646 and in contact with the top surface of the second metallic contact via structures (646 or 647); and a metallic material portion 662B overlying the metallic barrier liner 662A, wherein sidewalls of the metallic material portion 662B are vertically coincident with sidewalls of the metallic barrier liner 662A.

In one embodiment, the device structure comprises a three-dimensional memory array located over a substrate 9 and comprising an alternating stack (32, 46) of insulating layers 32 and electrically conductive layers 46 and a two-dimensional array of memory stack structures (50, 60) vertically extending through the alternating stack (32, 46), wherein: each of the memory stack structures (50, 60) comprises a respective vertical semiconductor channel 60 and a respective vertical stack of memory elements (e.g., portions of the memory film 50) located at levels of the electrically conductive layers 46; and the field effect transistors 610 comprise components of a peripheral circuit 612, which is located on the substrate 9 and is configured to control operation of the three-dimensional memory array. In one embodiment, the alternating stack (32, 46) comprises stepped surfaces; a retro-stepped dielectric material portion (such as a first retro-stepped dielectric material portion 165) overlies the stepped surfaces of the alternating stack (32, 46); and a metal interconnect structure (e.g., comprising a first-tier integrated line-and-via structure 682) comprising a metal via portion vertically extends through the retro-stepped dielectric material portion (such as a first retro-stepped dielectric material portion 165) and contacts a top surface of the metallic structure 662.

In one embodiment, the alternating stack (32, 46) comprises stepped surfaces; a retro-stepped dielectric material portion (such as a first retro-stepped dielectric material portion 165) overlies the stepped surfaces of the alternating stack (32, 46); and the metallic structure (662 or 682) comprises a first metal via portion contacting the top surface of the first metallic contact via structures 646 and a second metal via portion contacting a top surface of the second metallic contact via structures (646 or 647). In one embodiment, the metallic structure (662 or 682) comprises an integrated line-and-via structure (such as a first-tier integrated line and via structure 682) which comprises a metal line portion having a top surface located within a horizontal plane including a top surface of the retro-stepped dielectric material portion (such as a first retro-stepped dielectric material portion 165) and connected to, and overlying, the first metal via portion and the second metal via portion.

The various local interconnect structures (642, 643, 646, 647, 662 and/or 682) of the present disclosure shortens the wiring distance between the field effect transistors 610 within a semiconductor circuit, which may be a peripheral circuit 612 configured to drive a three-dimensional memory array. The semiconductor pillar structures (642, 643) and the metallic contact via structures (646 or 647) provide vertically-extending segments of the local interconnect structures (642, 643, 646, 647, 662 and/or 682). The metallic line structures 662 provide horizontally-extending segments of the local interconnect structures (642, 643, 646, 647, 662 and/or 682) in the first and third embodiments. Via portions of the first-tier integrated line-and-via structures 682 (if employed) provide vertically-extending segments of the local interconnect structures (642, 643, 646, 647, 662 and/or 682). The metal line portions of the first-tier integrated line-and-via structures 682 (if employed) provide horizontally-extending segments of the local interconnect structures (642, 643, 646, 647, 662 and/or 682) in the first and second embodiments.

The local interconnect structures (642, 643, 646, 647, 662 and/or 682) can reduce the capacitance between adjacent via contacts to the nodes of the field effect transistors 610. Thus, the local interconnect structures (642, 643, 646, 647, 662 and/or 682) can be employed to reduce propagation delay time of the field effect transistors 610 (e.g., of the CMOS inverter (610P, 610N)). For example, the field effect transistors 610 may be located in an input/output circuit which is connected to a controller located outside the memory chip. The input/output circuit may be part of the peripheral circuit 612, but may operate at a higher speed than sense amplifier and word line switching circuit portions of the peripheral circuit 612. Thus, the reduction in the propagation delay time of such field effect transistors 610 is particularly advantageous.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a first field effect transistor;
a second field effect transistor; and
a local interconnect structure comprising:
a first semiconductor pillar structure contacting a top surface of an active region of the first field effect transistor;
a first metallic contact via structure contacting a top surface of the first semiconductor pillar structure;
a metallic structure contacting a top surface of the first metallic contact via structure; and
a second metallic contact via structure contacting a bottom surface of the metallic structure and electrically connected to an electrical node of the second field effect transistor.

2. The device structure of claim 1, wherein:
the first field effect transistor comprises a stack of a first gate dielectric, a first gate electrode, and a first gate cap dielectric; and
a top surface of the first metallic contact via structure and a top surface of the second metallic contact via structure are located within a horizontal plane including a top surface of the first gate cap dielectric.

3. The device structure of claim 1, further comprising a gate-level dielectric layer laterally surrounding gate electrodes of the field effect transistors, wherein a top surface of the first metallic contact via structure and a top surface of the second metallic contact via structure are located within a horizontal plane including a topmost surface of the gate-level dielectric layer.

4. The device structure of claim 3, wherein:
the first field effect transistor comprises a first gate electrode and a first gate cap dielectric that overlies the first gate electrode; and
a top surface of the first gate cap dielectric is located within the horizontal plane.

5. The device structure of claim 1, wherein the electrical node of the second field effect transistor comprises an active region of the second field effect transistor.

6. The device structure of claim 5, further comprising a second semiconductor pillar structure contacting a top surface of the active region of the second field effect transistor and contacting a bottom surface of the second metallic contact via structure.

7. The device structure of claim 6, wherein:
the first semiconductor pillar structure consists essentially of a first doped semiconductor material; and
the second semiconductor pillar structure consists essentially of a second doped semiconductor material having a same semiconductor material composition as the first semiconductor pillar structure.

8. The device structure of claim 1, wherein the electrical node of the second field effect transistor comprises a gate electrode of the second field effect transistor.

9. The device structure of claim 8, the second metallic contact via structure contacts a top surface of the gate electrode of the second field effect transistor.

10. The device structure of claim 1, wherein the metallic structure is in direct contact with a top surface of the second metallic contact via structure.

11. The device structure of claim 10, wherein the metallic structure comprises a metallic line structure which comprises:
a metallic barrier liner in contact with the top surface of the first metallic contact via structure and in contact with the top surface of the second metallic contact via structure; and
a metallic material portion overlying the metallic barrier liner,
wherein sidewalls of the metallic material portion are vertically coincident with sidewalls of the metallic barrier liner.

12. The device structure of claim 1, further comprising a three-dimensional memory array located over a substrate and comprising an alternating stack of insulating layers and electrically conductive layers and a two-dimensional array of memory stack structures vertically extending through the alternating stack, wherein:
each of the memory stack structures comprises a respective vertical semiconductor channel and a respective vertical stack of memory elements located at levels of the electrically conductive layers; and
the field effect transistors comprise components of a peripheral circuit, which is located on the substrate and is configured to control operation of the three-dimensional memory array.

13. The device structure of claim 12, wherein:
the alternating stack comprises stepped surfaces;
a retro-stepped dielectric material portion overlies the stepped surfaces of the alternating stack; and
a metal interconnect structure comprising a metal via portion vertically extends through the retro-stepped dielectric material portion and contacts a top surface of the metallic structure.

14. The device structure of claim 12, wherein:
the alternating stack comprises stepped surfaces;
a retro-stepped dielectric material portion overlies the stepped surfaces of the alternating stack; and
the metallic structure comprises a first metal via portion contacting the top surface of the first metallic contact via structure and a second metal via portion contacting a top surface of the second metallic contact via structure.

15. The device structure of claim 14, wherein the metallic structure comprises an integrated line-and-via structure which further comprises a metal line portion having a top surface located within a horizontal plane including a top surface of the retro-stepped dielectric material portion and connected to and overlying the first metal via portion and the second metal via portion.

16. A method of forming a device structure, comprising:
forming field effect transistors on a substrate, wherein the field effect transistors comprise gate stack structures including a respective gate dielectric, a respective gate electrode, and a respective gate cap dielectric;
forming a gate-level dielectric layer, wherein a topmost surface of the gate-level dielectric layer is formed within a horizontal plane including top surfaces of the gate cap dielectrics of the field effect transistors;
forming pedestal-contact via cavities through at least the gate-dielectric layer over a first subset of active regions of the field effect transistors;
forming semiconductor pillar structures in lower portions of the pedestal-contact via cavities, wherein the semiconductor pillar structures comprise a first semiconductor pillar structure contacting an active region of a first field effect transistor of the field effect transistors;
forming metallic contact via structures after formation of the semiconductor pillar structures, wherein the metallic contact via structures comprise a first metallic contact via structure that is formed on a top surface of the first semiconductor pillar structure and a second metallic contact via structure that is electrically connected to a node of a second field effect transistor of the field effect transistors; and
forming a metallic structure contacting a top surface of the first metallic contact via structure and the second metallic contact via structure.

17. The method of claim 16, wherein the metallic structure comprises a metallic line structure that is formed by:
depositing a metallic barrier liner layer and a metallic material layer over the first metallic contact via structure and the second metallic contact via structure; and
patterning the metallic material layer and the metallic barrier liner, wherein a continuous set of patterned portions of the metallic material layer and the metallic barrier liner layer comprises the metallic line structure.

18. The method of claim 16, further comprising:
forming a sacrificial dielectric layer on the topmost surface of the gate-level dielectric layer wherein the pedestal-contact via cavities comprise a first subset of contact-level cavities which are also formed through the sacrificial dielectric layer;
forming a second subset of the contact-level via cavities through the sacrificial dielectric layer and the a gate-level dielectric layer, wherein top surfaces of additional active regions of the field effect transistors are exposed under the second subset of the contact-level via cavities;
forming in-process contact via structures in the contact-level via cavities; and
removing the sacrificial dielectric layer and upper portions of the in-process contact via structures, wherein remaining lower portions of the in-process contact via structures comprise the metallic contact via structures.

19. The method of claim 16, wherein:
the node of the second field effect transistor comprises an active region of the second field effect transistor; and
the semiconductor pillar structures further comprise a second semiconductor pillar structure that is formed on the active region of the second field effect transistor and comprises a single-crystalline semiconductor material in epitaxial alignment with a single-crystalline material in the active region of the second field effect transistor.

20. The method of claim 16, wherein:
the node of the second field effect transistor comprises a gate electrode of the second field effect transistor; and
the second metallic contact via structure is formed through a gate cap dielectric of the second field effect transistor and contacts the gate electrode of the second field effect transistor.
